(19) United States
(12) Patent Application Publication
(10) Pub. No.: US 2014/0206112 A1
(43) Pub. Date: Jul. 24, 2014

(54) METHOD FOR REDUCING CHARGE IN CRITICAL DIMENSION-SCANNING ELECTRON MICROSCOPE METROLOGY

(71) Applicants: Sematech, Inc., Albany, NY (US); The Research Foundation for the State University of New York, Albany, NY (US)

(72) Inventors: MELVIN WARREN MONTGOMERY, North Greenbush, NY (US); Cecilia Annette Montgomery, North Greenbush, NY (US); Benjamin D. Bunday, Schenectady, NY (US)

(73) Assignees: Sematech, Inc., Albany, NY (US); The Research Foundation for the State University of New York, Albany, NY (US)

(21) Appl. No.: 14/157,804

(22) Filed: Jan. 17, 2014

Related U.S. Application Data
(60) Provisional application No. 61/754,148, filed on Jan. 18, 2013.

(51) Int. Cl. H01L 21/66; H01L 21/033

(52) U.S. Cl. CPC H01L 22/12; H01L 21/0337
USPC 438/16; 438/763; 524/588; 423/348; 252/500

(57) ABSTRACT

Methods and compositions are provided for reducing or eliminating charge buildup during scanning electron microscopy (SEM) metrology of a critical dimension (CD) in a structure produced by lithography. An under layer is utilized that comprises silicon in the construction of the structure. When the lithography structure comprising the silicon-comprising under layer is scanned for CDs using SEM, the under layer reduces or eliminates charge buildup during SEM metrological observations.

### CROSS-REFERENCE TO RELATED APPLICATIONS

This application claims priority to and the benefit of co-pending U.S. provisional patent application Ser. No. 61/754,148, entitled Method For Reducing Charge in Critical Dimension-Scanning Electron Microscope Metrology, filed Jan. 18, 2013, which is incorporated herein by reference in its entirety.

### 1. TECHNICAL FIELD

The present invention relates to methods and compositions for reducing charge buildup and improving the accuracy of measurement in critical dimension-scanning electron microscope (CD-SEM) metrology. The invention also relates to methods and compositions for constructing integrated circuits or devices that can be more accurately or precisely measured by CD-SEM metrology.

### 2. BACKGROUND OF THE INVENTION

Measurement and inspection of critical dimensions (CDs) of lithographically patterned features produced in the manufacture of integrated circuits utilizes scanning electron microscopy (SEM) to determine whether target patterns are generated at desired or required tolerances. SEM is currently capable of accurately measuring features during the volume manufacture of integrated wafers. SEM metrology can yield accurate and rapid measurements of features on silicon wafers during manufacturing. Since these features are typically isolated from the electrical ground of the microscope by virtue of their circuit design, this can create a charge build up from the electron beam in the SEM.

A major problem in using SEM for metrology of CDs is that as the target feature size decreases, the impact of charging increases. The buildup of surface charge on a specimen caused by the electron beam of the SEM will thus cause gross image distortion or image obliteration. Such image distortion or obliteration has led to an increasing inability to accurately measure critical integrated device dimensions in the electronic industry. Since CDs are becoming increasingly smaller as lithographic technology advances, such inaccuracies pose a significant problem in the manufacture of integrated circuits. Target CD pitches are tightening (and confined spaces between features tightens as a result); this exacerbates charge build-up. Charge buildup is expected to become a larger variable error component for CD-SEM metrology as new technologies such as extreme ultraviolet (EUV) lithography (EUVL), electronic beam (e-beam) direct write techniques, nano imprint techniques and multiple patterning techniques are introduced.

Current methods for reducing or eliminating charge buildup involve changing the feature to be measured, e.g., implanting the material to be measured with a charge-reducing material. For example, U.S. Pat. No. 5,783,366 to Chen et al. discloses a method for eliminating charging of photoresist on specimens during scanning electron microscope examination by ion implantation.

U.S. Pat. No. 6,774,365 to Okoroanyanwu et al. discloses a method for transforming the surface of the photoresist layer using an electron beam (e-beam) before performing SEM metrology. The surface of the photoresist layer is transformed to trap outgassing volatile species and to dissipate charge buildup in the photoresist layer.

U.S. Pat. No. 6,479,820 to Singh et al. discloses a multi-step method for processing a photoresist on a semiconductor structure in which the photoresist is evaluated to determine if negative charges exist on it and contacting the photoresist with a positive ion carrier to reduce negative charge build up, then re-evaluating the photoresist.

Others have addressed this problem by creating a stack that can neutralize the charge. For example, U.S. Pat. No. 5,736,863 to Liu discloses fabricating independent inspection test structures on designated sites on a wafer that are designed to provide a reduction or elimination of charge build up during SEM observation. This approach, however, requires changing the stack that will be used for constructing the device of interest.

U.S. Pat. No. 7,910,283 to Ogihara et al. discloses a composition for forming an anti-reflective coating for use in a photolithography process using exposure light of up to 200 nm. The composition comprises a silicon-containing polymer obtained through hydrolytic condensation of a silicon-silicon bond-containing silane compound having formula: R(6-m)Si2Xm wherein R is a monovalent hydrocarbon group, X is alkoxy, alkanoyloxy or halogen, and m is 3 to 6. The composition allows the overlying photoresist film to be patterned to a satisfactory profile and has a high etching selectivity relative to organic material so that a substrate can be processed at a high accuracy. U.S. Pat. No. 7,910,283 also discloses that SiARC can be used as an imaging layer that can be used (because of the silicon content) to block oxygen etching.

As described above, present techniques in the field require that a feature to be measured be changed, for example, implanting the material to be measured. The present techniques address this problem by creating, for example, a special stack that can neutralize built-up charge, but this requires changing the stack that will be used for the desired integrated device to be constructed.

Citation or identification of any reference in Section 2, or in any other section of this application, shall not be considered an admission that such reference is available as prior art to the present invention.

### 3. SUMMARY OF THE INVENTION

A method for producing a surface of interest in the manufacture of an integrated device is provided, the method comprising the steps of:

(a) providing a substrate;

(b) positioning a silicon-comprising under layer on the substrate; and

(c) positioning a patterned photoresist image layer on the under layer.

In one embodiment of this first method, the surface is lithographically or non-lithographically fabricated.

In another embodiment of this first method, the silicon-comprising under layer comprises a nondoped or doped conjugated or conducting polymer comprising silicon.

In another embodiment of this first method, the silicon-comprising under layer of claim 1 comprises a silicon-containing antireflection coating (SiARC).

In another embodiment of this first method, step (b), the step of positioning a silicon-comprising under layer on the substrate, comprises the steps of depositing an organic layer and depositing silicon on the organic layer.

In another embodiment of this first method, the step of depositing silicon on the organic layer comprises the step of vapor-depositing silicon on the organic layer or the step of silylating the organic layer.

In another embodiment of this first method, the substrate comprises silicon.

In another embodiment of this first method, the silicon-comprising substrate is a silicon wafer.

In another embodiment of this first method, step (c), the step of positioning the patterned photoresist image layer on the silicon-comprising under layer comprises spin coating the photoresist image layer on the under layer.

In another embodiment of this first method, the patterned photoresist image layer comprises at least one structure defining an opening in the patterned photoresist image layer.

In another embodiment of this first method, the structure defining the opening is dimensionally equivalent to a desired opening in the integrated device.

In another embodiment of this first method, the lithographically fabricated surface comprises a feature having at least one critical dimension (CD).

A second method is also provided, which is a method for inspecting or measuring a feature on a lithographically fabricated surface of interest in the manufacture of an integrated device, the method comprising the steps of:

(a) providing a substrate;

(b) positioning a silicon-comprising under layer on the substrate;

(c) positioning a patterned photoresist image layer on the under layer; and

(d) delivering an electron beam to the surface of interest.

In one embodiment of this second method, the surface is lithographically or non-lithographically fabricated.

In another embodiment of this second method, the silicon-comprising under layer comprises a nondoped or doped conjugated or conducting polymer comprising silicon.

In another embodiment of this second method, the under layer comprises a silicon-containing antireflection coating (SiARC).

In another embodiment of this second method, step (b), the step of positioning a silicon-comprising under layer on the substrate, comprises the steps of depositing an organic layer and depositing silicon on the organic layer.

In another embodiment of this second method, the step of depositing silicon on the organic layer comprises the step of vapor-depositing silicon on the organic layer or the step of silylating the organic layer.

In another embodiment of this second method, the substrate comprises silicon.

In another embodiment of this second method, the silicon-comprising substrate is a silicon wafer.

In another embodiment of this second method, step (c), the step of positioning the patterned photoresist image layer on the silicon-comprising under layer comprises spin coating the photoresist image layer on the under layer.

In another embodiment of this second method, the patterned photoresist image layer comprises at least one structure defining an opening in the patterned photoresist image layer.

In another embodiment of this second method, the structure defining the opening is dimensionally equivalent to a desired opening in the integrated device.

In another embodiment of this second method, the lithographically fabricated surface comprises a feature having at least one critical dimension (CD).

An under layer (or under layer composition) comprising silicon is also provided.

In one embodiment of the under layer, the under layer comprises a nondoped or doped conjugated or conducting polymer comprising silicon.

In another embodiment of the under layer, the under layer comprises a SiARC (silicon-containing antireflection coating).

In another embodiment of the under layer, the under layer comprises: a nondoped or doped conjugated or conducting polymer comprising silicon, and/or a silicon-containing antireflection coating (SiARC).

### 4. BRIEF DESCRIPTION OF THE DRAWINGS

The present invention is described herein with reference to the accompanying drawings, in which similar reference characters denote similar elements throughout the several views. It is to be understood that in some instances, various aspects of the invention may be shown exaggerated or enlarged to facilitate an understanding of the invention.

FIG. 1. Silicon-comprising under layer comprising a SiARC (“SiARC”) positioned on a substrate, with a photoresist positioned on the silicon-comprising under layer.

FIG. 2. Design of experiment (DOE) of photoresist used in Section 6.1, Example 1, including some process parameters. The numbers under the resist labels are layer thicknesses, in units of nm.

FIGS. 3a-0 to 3a-4. Charging behavior for sub-30 nm extreme ultraviolet (EUV) resist features in the CD-SEM. FIGS. 3a-0 shows an overview of charging behavior at 500V of resist B on underlayer E. FIGS. 3a-1 to 3a-4 show enlargements of the graphs and diagrams shown in FIG. 3a-0.

FIGS. 3b-0 to 3b-4. Charging behavior for sub-30 nm EUV resist features in the CD-SEM. FIG. 3b-0 shows an overview of charging behavior at 500V of resist B on underlayer D. FIGS. 3b-1 to 3b-4 show enlargements of the graphs and diagrams shown in FIG. 3b-0.

FIGS. 4-0 to 4-7. Charging behavior for sub-30 nm EUV resist features in the CD-SEM with non SiARC under layer. FIG. 4-0 shows an overview of this charging behavior. FIGS. 4-1 to 4-7 show enlargements of the graphs and diagrams shown in FIG. 4-0.

FIG. 5. 193 nm polymer-bound PAG photoresist example from reference [9] (J. Thackeray, J. Cameron, M. Wagner, S. Coley, O. Ongayi, W. Montgomery, D. Lovell, J. Biafore, A. Ko, “Optimization of Low Diffusion EUV Resist for Linewidth Roughness and Pattern Collapse on Various Substrates”, Proc. SPIE Paper #8325-8 in press (2012)).

FIG. 6. 248 nm-type base polymer.

FIG. 7. Shrinkage from ArF resist with exposure to an electron beam. This is a major issue with current and future CD measurements of lithographic features in semiconductor manufacturing, as it is a source of systematic measurement error due to the beam interacting with the sample, which influences both accuracy (due to “0th shrink”) and precision (due to the trend with the number of measurements, which is a measure of dose).

FIG. 8. Damage on an etched a-Si feature at the site of previous CD-SEM measurement of the previous photoresist layer.

FIG. 9. Dynamic shrinkage results showing how first shrink (difference between first and second SEM measurements) varies as a function of time after the 1st measurement (i.e., time from initial exposure of the measurement site to electron beam). Results are plotted on a logarithmic time scale.

FIG. 10. Descriptions, timings and experimental purpose of the three site groups a, b, and s described in Section 6.2, Example 2.

FIG. 11. The different measurement runs performed at each die for the dynamic effects experiment. The time t1 between Run 1 and Run 2 is the main variable in the DOE; variation of t1 results in the time for measuring the 2nd measurement of site group a and the time of the 1st measurement of site groups b and s also vary. Varying t1 is achieved by running different columns of all the recipes at different times, according to the run schedule for different die/columns as shown in FIG. 12.

FIG. 12. SEM measurement die map and timetable. The wafer included 7 columns by 5 rows of nominally identical die (only one of the identical five rows is shown, for brevity). Each column was measured at different times per the timetable across the bottom. All 5 die within each column and 3-5 lines per die were measured at the same time to collect enough data for averaging to ensure statistical validity of the results. Each site was measured once at site group a when the wafer was fresh off the lithocell, at time 0. Then a series of recipes was run for the appropriate die columns and site groups according to this timetable and die map.

FIG. 13. Static shrinkage curves for 30 nm, 40 nm and 50 nm dense features for resist A (baseline 193 nm-type), at 500 V, 300 V, and 800 V.

FIG. 14. Static shrinkage curves for 30 nm, 40 nm and 50 nm dense features for resist B (193 nm-type), at 500 V.

FIG. 15. Static shrinkage curves for 30 nm, 40 nm and 50 nm dense features for resist C (248 nm-type), at 500 V.

FIGS. 16a-b. Dynamic effect and CD independence of age graphs for resist A (baseline 193 nm-type), at 500 V, 300 V, and 800 V.

FIG. 17. Dynamic effect and CD independence of age graphs for resist B (193 nm-type), at 500 V.

FIG. 18. Dynamic effect and CD independence of age graphs for resist C (248 nm-type), at 500 V.

FIGS. 19a-h. Charging evidence for wafer 18b, resist B. a, b, c): 1st, 2nd and 10th images, respectively, from the static measurements of 30 nm dense line features. d, e, f): 1st, 2nd and 10th images, respectively, from the static measurements of 30 nm isolated space features. g): graph comparing the intensity linescans of the 1st, 2nd and 10th images of the static measurements of the 30 nm dense line features. h): graph comparing the intensity linescans of the 1st, 2nd and 10th images of the static measurements of the 30 nm isolated space feature.

FIG. 20. Illustration of competing shrinkage and charging effects on the CD measurement, and the resulting static measurement curve.

FIG. 21. Example fit of the SEMATECH 2D-profile resist shrinkage model, in this case for resist A at 500 V. Each data curve represents the static measurements of one of the six features measured on this wafer with the given CD-SEM condition (30 nm, 40 nm and 50 nm dense lines, plus some similar isolated lines), and then all curves are simultaneously fit by the model with identical parameters, except that each feature is described by a different trapezoidal profile. For reasonable profile inputs, reasonable shrinkage parameters were solved; =80% is typical.

FIG. 22. Summary of results of experiments described in Section 6.2, Example 2.

### 5. DETAILED DESCRIPTION OF THE INVENTION

Methods and compositions are provided for reducing or eliminating charge buildup during scanning electron microscopy (SEM) metrology of a critical dimension (CD) or of a plurality of CDs in a structure. The methods and compositions provided can be used to increase the accuracy of measurement in critical dimension-scanning electron microscope (CD-SEM) metrology.

Methods and compositions are also provided for constructing integrated circuits or devices that can be more accurately or precisely measured by CD-SEM metrology.

The specimen, structure or component to be measured can be produced by lithographic methods (also referred to herein as a “lithography structure” or a “lithographic structure”) or it can be produced by non-lithographic methods. In a specific embodiment, the structure is an integrated circuit.

The methods and compositions provided herein can be used for reducing or eliminating charge buildup during scanning electron microscopy (SEM) metrology in any structure viewed in a scanning electron microscope. For example, biological samples, which are often viewed in SEM, are frequently subject to charging. Charging is a well-known problem with organic specimens and poorly conducting inorganic materials. The methods and compositions provided herein can be applied to CD-SEM metrology of any organic specimen, structure or component (plant or animal cell, tissue sample, microorganism, whole animal such as arthropod (e.g., mite, insect), to name but a few). The methods and compositions provided herein can also be applied to a specimen, structure or component comprising a poorly conducting inorganic material, e g a milled and/or inorganic semi metallic structure.

In one embodiment, an under layer is utilized that comprises silicon (also referred to herein as a “silicon-comprising” (“SC”) under layer or under layer composition) in the construction of the structure. When the lithography structure comprising the SC under layer is scanned for CDs using SEM, the under layer reduces or eliminates charge buildup during SEM metrological observations.

One advantage of the present invention is that it provides a method for producing a desired stacked lithographic structure that utilizes the stack as engineered and simply utilizes a silicon under layer, effectively an under layer that comprises a group four element other than Carbon (C).

An under layer comprising silicon has been previously used in the art as an antireflective coating that can then be used as a hardmask, which is used to define a pattern during etching in an oxygen-containing environment. The inventors have discovered, however, that a silicon-comprising under layer can be used to mitigate charge buildup during SEM metrology. The present invention employs a silicon under layer at extreme ultraviolet (EUV) specifically, and other wavelengths to mitigate charging as a major impact, so that sub-20 nm patterning may be achieved.

A method is for reducing charge build up is provided comprising the step of coating a layer of imaged photoresist on an under layer (also referred to herein as a bottom coating) comprising silicon, wherein the under layer and the layer of imaged photoresist form two layers of a lithography stack. The under layer renders the photoresist pattern resistant to charging during scanning electron microscopy (SEM). Accumulation of surface charge is known to occur, during CD measurement and inspection lithographically generated patterns, manifesting as gross image distortion and leading to CD measurement error. The method is particularly useful when used on post developed photoresist patterns.

Since semiconductor patterns are reducing in size, as the industry migrates to EUV lithography, tighter pattern density creates microenvironment where electron charge concentrates. Utilizing the spin-able film stack disclosed herein is a cost-effective solution to controlling measurement the error caused by charging.

In one embodiment, a structure with at least one CD of interest is built on a under layer comprising silicon using successive (or reiterative) lithographic process steps. Such lithographic steps are known in the art, and the same lithography step can be performed repeatedly to create a layered device (wafer). The reduction or elimination of charge buildup allows much enhanced resolution and accurate measurements of CDs.

In a preferred embodiment, extreme ultraviolet lithography (EUVL) is employed to construct an integrated circuit or integrated device, and the silicon-comprising under layer is used to mitigate charge accumulation and its detrimental impact on SEM metrology. EUVL methods are known in the art.

Extreme ultraviolet lithography (also known EUVL) is a next-generation lithography technology using an extreme ultraviolet (EUV) wavelength. Extreme ultraviolet radiation (EUV or XUV) is high-energy ultraviolet radiation of wavelengths in the range of 10 nm-124 nm, and therefore (by the Planck-Einstein equation) having photons with energies from 10 eV up to 124 eV (corresponding to 124 nm to 10 nm respectively).

In a specific embodiment, the wavelength is in the range of 10-20 nm.

The silicon-comprising underlayer can also be used at other wavelengths, e.g., 10 nm-650 nm, to mitigate charging.

For clarity of disclosure, and not by way of limitation, the detailed description of the invention is divided into the subsections set forth below.

5.1. Silicon-Comprising Under Layer for Reducing or Eliminating Charge Buildup

Materials and methods are provided for reducing or eliminating charge buildup during scanning electron microscopy (SEM) metrology of a critical dimension (CD) or of a plurality of CDs in a structure. In one embodiment of the method, the structure comprising the CD to be measured is produced by lithography (also referred to herein as a “lithography structure” or a “lithographic structure”). In other embodiments, the structure comprising the CD to be measured is produced by a non-lithographic method, e.g., imprint technology.

In one embodiment, a method for producing a surface of interest in the manufacture of an integrated device is provided, the method comprising the steps of:

(a) providing a substrate;

(b) positioning a silicon-comprising under layer on the substrate; and

(c) positioning a patterned photoresist image layer on the under layer.

In another embodiment, a composition comprising silicon is provided for use in measuring and inspecting a lithographically fabricated surface. The lithographically fabricated surface is then used in the manufacture of an integrated circuit or device. The silicon-comprising composition can be applied or coated as an under layer (also referred to herein as a “silicon-comprising” or “SC” under layer). According to the invention, a layer of imaged photoresist can be lithographically coated on the silicon-comprising under layer, thereby forming a photoresist layer in a lithography stack. The silicon-comprising under layer renders a photoresist pattern formed in the photoresist layer resistant to charging during SEM metrology.

The under layer can comprise a nondoped or doped conjugated or conducting polymer comprising silicon. Conducting polymers are known in the art as effective discharge layers as well as conducting resists in electron beam lithography, providing excellent electrostatic discharge protection for packages and housings of electronic equipment (see, e.g., Angelopoulos, M. “Conducting polymers in microelectronics”, IBM J. Res. & Dev. Vol. No. 1 January 2001, 57-75, incorporated herein by reference in its entirety).

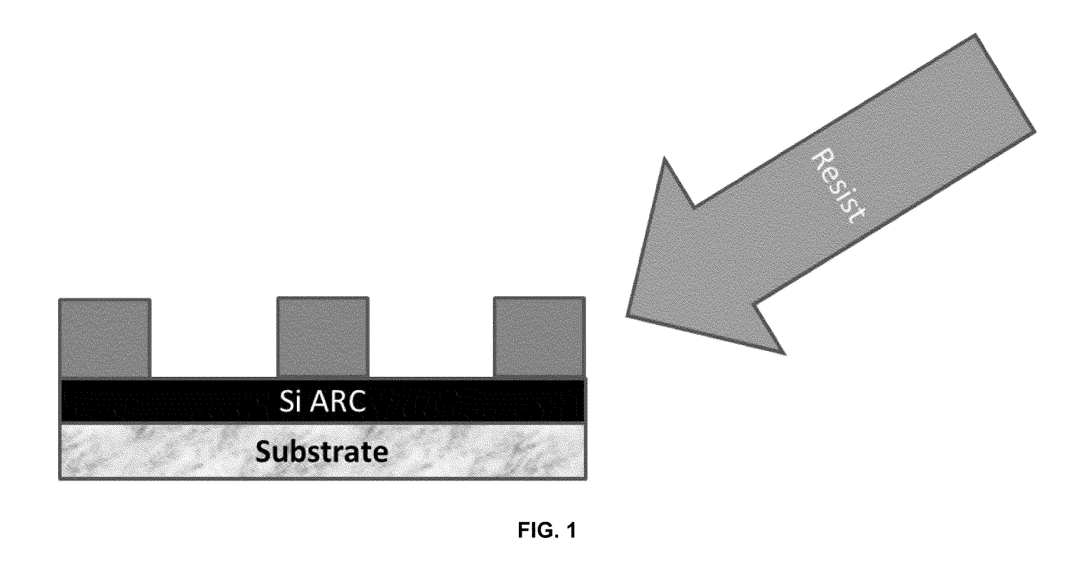

In a preferred embodiment, the under layer comprises silicon. In a specific embodiment, the silicon-comprising under layer comprises a SiARC (silicon-containing antireflection coating). SiARCs are compatible with most photoresist used for high resolution imaging. FIG. 1 shows a silicon-comprising under layer comprising a SiARC (“SiARC”) positioned on a substrate, with a photoresist positioned on the under layer.

SiARCs are commercially available in proprietary compositions (e.g., SHBA 940, Shin Etsu Chemical Co., Ltd., Tokyo, Japan). The Shin Etsu SHBA 940 SiARC has been previously used in the art for reflection control in advanced semiconductor manufacturing in the range of 22-45 nm (see, e.g., Wei, Y. et al. Performance of tri-layer process required for 22 nm and beyond. Proc. SPIE 7972, 79722L (2011); http://dx.doi.org/10.1117/12.879301, incorporated herein by reference in its entirety).

In another embodiment, art-known techniques such as vapor deposition or silylation can be used to deposit silicon (Si) on an organic layer to form a silicon-comprising under layer. The organic layer onto which Si is deposited can be any photoresist that does not contain Si. For example, a resin solution can be used as the organic layer, wherein one or a mixture of resin components is mixed in an appropriate solvent known in the art. Such components can include, but are not limited to, polyhydroxystyrene, poly(methyl methacrylate) (PMMA), poly(methyl glutarimide) (PMGI), phenol formaldehyde resin (DNQ/Novolac, Novalak, Resol), SU-8 photoresist, polyamic acid, copolymer of methyl methacrylate (MMA) and methacrylic acid (MAA), cycloolefin-maleic anhydride polymers with acrylic acid (AA), norbomene hexafluoroalcohol (NBHFA)

5.2. Method for Reducing or Eliminating Charge Buildup on a Structure

A method is provided for reducing or eliminating charge buildup during scanning electron microscopy (SEM) metrology of a feature of interest in a structure. In one embodiment, the structure is produced by lithography (also referred to herein as a “lithography structure” or a “lithographic structure”). In a preferred embodiment, the structure is produced by EUV lithography.

The feature can have at least one critical dimension (CD), or a plurality of CDs, to be measured using SEM metrology. The method can comprise the step of utilizing an under layer comprising silicon (also referred to herein as a “silicon-comprising” or “SC” under layer) in the construction of the lithographic structure.

In a specific embodiment, the method comprises the steps of providing a silicon-comprising under layer; and lithographically coating a layer of imaged photoresist on the silicon-comprising under layer, thereby forming a photoresist layer in a lithography stack and rendering the photoresist pattern resistant to charging during scanning electron microscopy.

Accumulation of surface charge is known to occur during CD measurement and inspection of lithographically generated patterns, manifesting as gross image distortion and leading to CD measurement error. The method provided herein is particularly useful when used on post-developed photoresist patterns. As technology advances and the industry migrates to EUV lithography, semiconductor patterns are decreasing in size. Tighter pattern density creates a microenvironment where electron charge can concentrate. The method provided herein can reduce or eliminate this charge build up.

In one embodiment, a method is provided for producing a lithographically fabricated surface of interest in the manufacture of an integrated device, the method comprising the steps of:

(a) providing a substrate;
(b) positioning an under layer comprising silicon on the substrate; and
(c) positioning a patterned photoresist image layer on the under layer.

In another embodiment, the silicon-comprising under layer comprises a nondoped or doped conjugated or conducting polymer comprising silicon. Conducting polymers are known in the art as effective discharge layers as well as conducting resists in electron beam lithography, providing excellent electrostatic discharge protection for packages and housings of electronic equipment (see, e.g., Angelopoulos, M. “Conducting polymers in microelectronics”, IBM J. Res. & Dev. Vol. 45 No. 1 January 2001, 57-75). In a specific embodiment, the silicon-comprising under layer comprises a SiARC (silicon-containing antireflection coating).

The substrate forms the base of a lithographic stack in the production of a device comprising at least one integrated circuit (also referred to herein as an “integrated device”). The substrate typically comprises silicon, and can be, for example a silicon wafer. In other embodiment, other substrates such as graphene can also be used.

The patterned photoresist image layer can comprise any suitable photoresist material known in the art. The patterned photoresist image layer comprises at least one structure defining an opening in the patterned photoresist image layer. This structure can define an opening that is dimensionally equivalent to a desired opening in the integrated device.

The step of positioning the patterned photoresist image layer on the silicon-comprising under layer can be accomplished by any suitable method known in the art. In a specific embodiment, spin coating is used to apply the photoresist. Spin coating of uncured elastomers is a well-known technique for applying photoresists. Using a low-cost “spinable” lithographic stack is a cost effective solution to reducing the metrology errors caused by charge buildup.

In a specific embodiment of the method, a photoresist image layer that has been patterned using lithography is coated on the silicon-comprising under layer. A lithographic stack is thereby produced that comprises a substrate (e.g., a silicon wafer), a silicon-comprising under (or middle) layer and a photoresist image (top) layer on the silicon-comprising under layer. An opening or plurality of openings in the photoresist (top) layer is patterned photolithographically by exposing the photoresist. The photoresist is developed to yield a desired opening or pattern of openings, e.g., lines, spaces, contact holes, posts, etc.

5.3. Metrology Method

In another embodiment, a metrology method is provided, i.e., a method for inspecting or measuring a feature of interest on a lithographically fabricated surface of interest in the manufacture of an integrated device. The metrology method improves the accuracy of measurement by employing the silicon-comprising under layer to reduce charge build up during measurement by employing an electron beam. This metrology method is useful for measuring and inspecting a lithographically fabricated surface, which surface is then used in the manufacture of an integrated device.

The method can comprise the steps of:

(a) providing a substrate;
(b) positioning an under layer comprising silicon on the substrate; and
(c) positioning a patterned photoresist image layer on the under layer.

In certain embodiment, the method can further comprise:

(d) delivering an electron beam to the surface of interest; and
(e) measuring the feature of interest using the electron beam.

In a specific embodiment, the measuring step comprises employing scanning electron microscopy (SEM).

The following examples are offered by way of illustration and not by way of limitation.

### 6. EXAMPLES

### 6.1. Example 1

### Charging of Extreme Ultraviolet (EUV) Photoresist Targets in Critical Dimension Scanning Electron Microscopy (CD-SEM)

This example demonstrates that a silicon-comprising coating can be applied as a film to coat a photoresist sample to mitigate sample charging. The SiARC SHBA 940 (Shin Etsu, Tokyo, Japan) is typically used as a hardmask for tri-layer image processing and to define patterns in organic films via O₂ plasma etching (Wei, Yet al. 2011. Proc. SPIE 7972, 79722L (2011). According to techniques currently practiced in the art, discharge layers can be coated on top of the imaging layer of a photoresist prior to electron beam exposure to help reduce or eliminate the charge build up that deflects the electron beam during exposure. The discharge layers, however, do not contain silicon nor have they been applied under a photoresist layer for the purpose of mitigating charging. This example shows that using SiARC as an underlayer for sub-30 nm photoresist images reduces or eliminates local charging.

6.1.1. Experimental Approach

The photocluster used in this study consisted of the ASML Alpha Demo Tool (ADT) in Albany, N.Y. which is interfaced with a TEL ACT-12 coating track (these tools are located at the CNSE site and managed by CNSE). The ADT currently uses conventional illumination and has a 0.25NA.

Two commercially available methacrylate based EUV resist formulations, Shin Etsu SEVR-139 (ArF based formulation) and Dow (193 nm based), and two commercially available polyhydroxystyrene-based photoresist formulations, Dow XP 5271P (248 nm based formulation) and DOW XE100613EAA (ArF based formulation) (Dow Electronic Materials, Marlboro, Mass.), were evaluated on one of two different underlayer formulations.

Underlayer 1 was SiARC SHBA 940 (Shin Etsu, Tokyo, Japan) (“SiARC”). Underlayer 2 was a carbon-containing, non-silicon containing, organic underlayer, DOW XU090640BB (Dow Corning Corporation, Midland, Mich.) (“OrganicARC”).

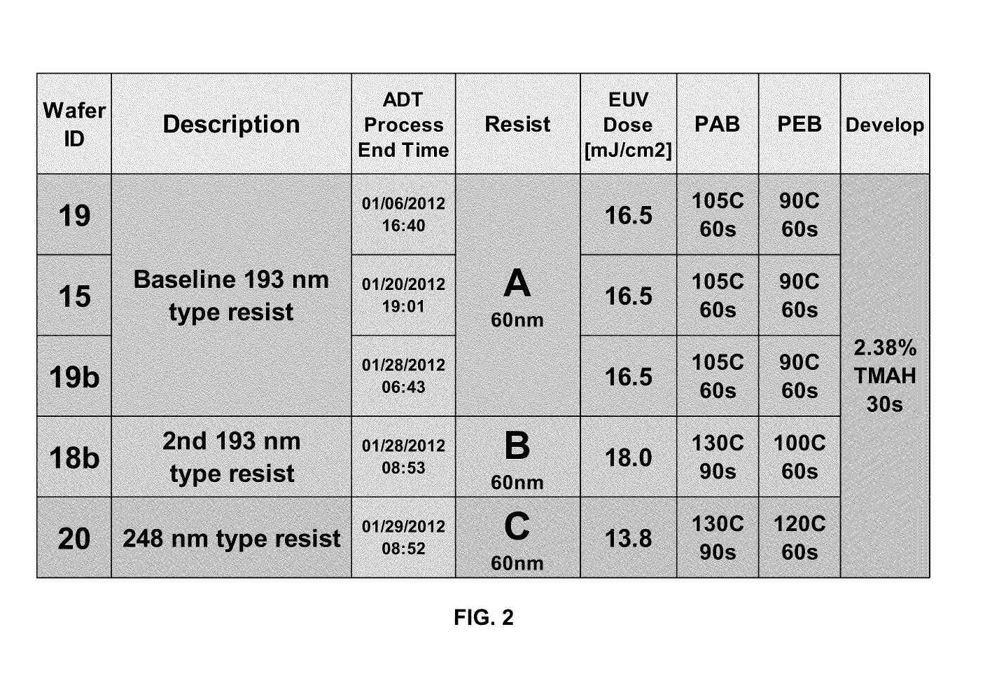

Resist mixtures were spun-cast on 300 mm Si wafers coated with a ˜25 nm adhesion underlayer and a 60 nm thick resist. The films were post-apply baked (PAB) at times and temperatures specified in FIG. 2 and were exposed to the EUV light source (NA=0.25; conventional illumination). The exposed wafers were post-exposure baked (PEB) at the times and temperatures specified in FIG. 2. Finally, all samples were processed according to supplier recommended methods included with the commercial product, using 0.26N tetramethylammonium hydroxide (TMAH) solution for 30 seconds.

All samples were exposed using a photocluster, the ASML Alpha Demo Tool (ADT), which is interfaced with a TEL ACT-12 coating track (these tools are located at Albany University, Center for Nanoscale Science and Engineering, Albany N.Y.). The ADT uses conventional illumination and has a 0.25NA.

For each resist, the best exposure conditions were found by printing focus/exposure matrix (FEM) wafers to best print 30 nm, 40 nm, and 50 nm 1:1 (dense) line/space features. Constant focus/exposure wafers at these best conditions were then exposed and developed. The timestamps were recorded from the lithocell for when each wafer was completed. Each wafer was exposed with the same reticle, the CNSE INVENT reticle. Measurements were taken at the center of the slit in the exposure field. The wafer map consisted of a 5 row by 7 column array, with a die size of 26×33 mm on a 300 mm diameter wafer. FIG. 2 presents the details of the DOE, along with process parameters.

6.1.2. Results

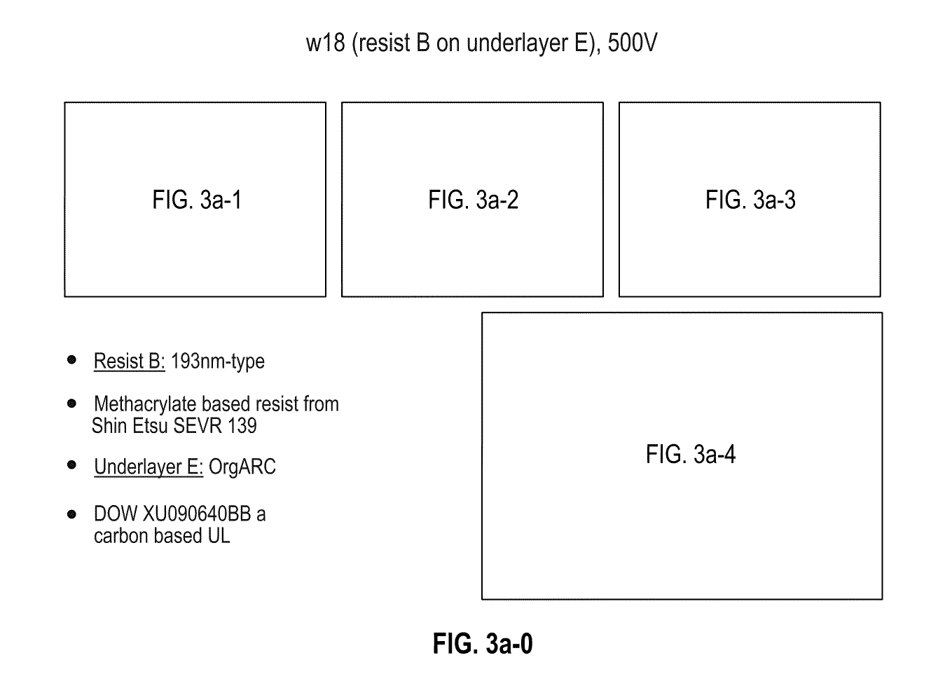

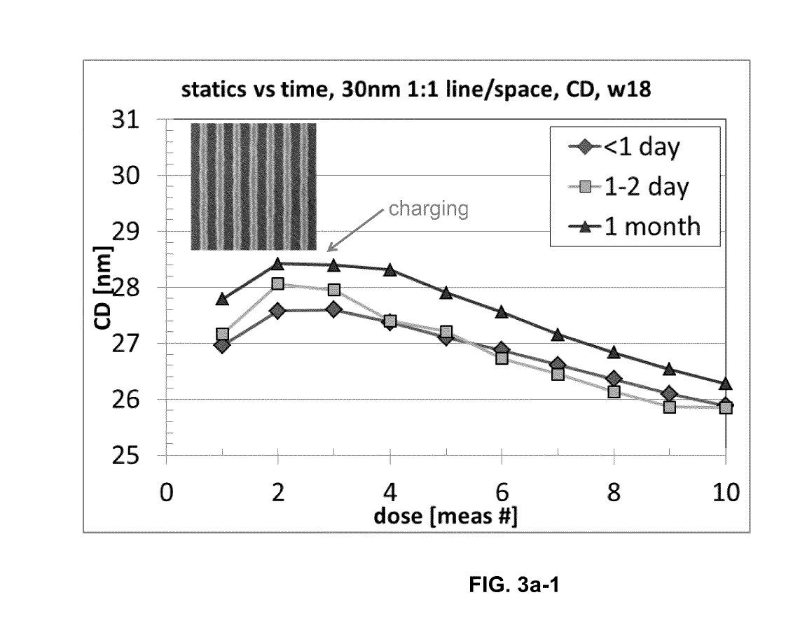

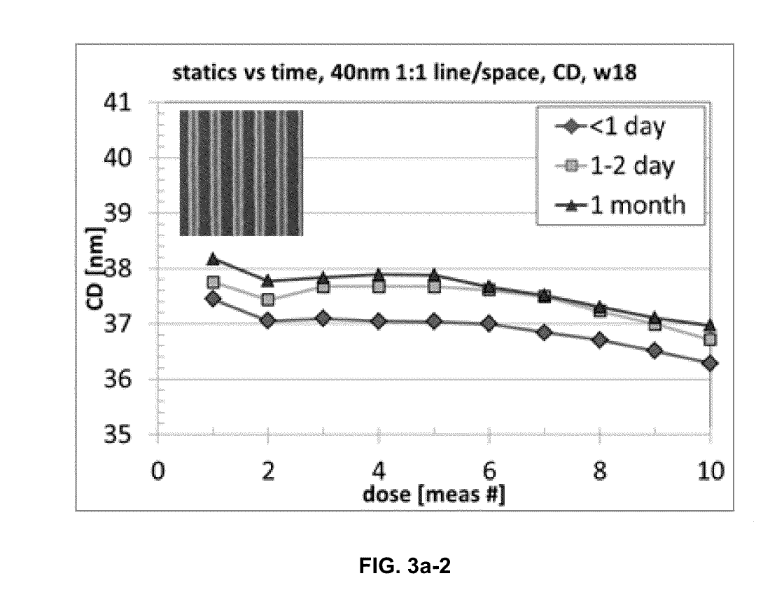

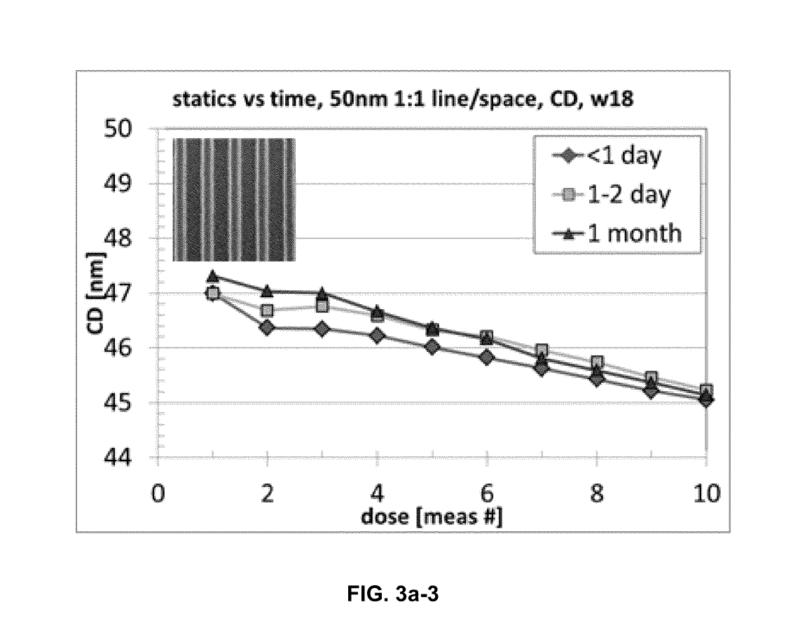

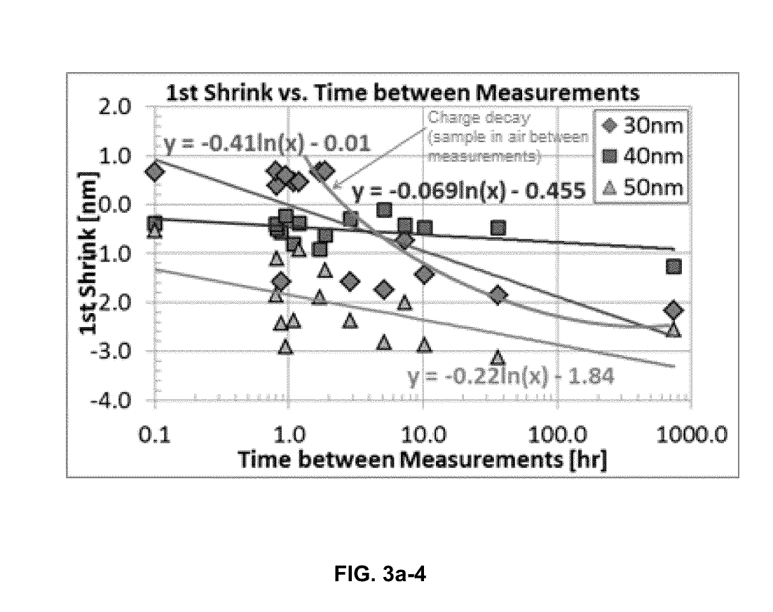

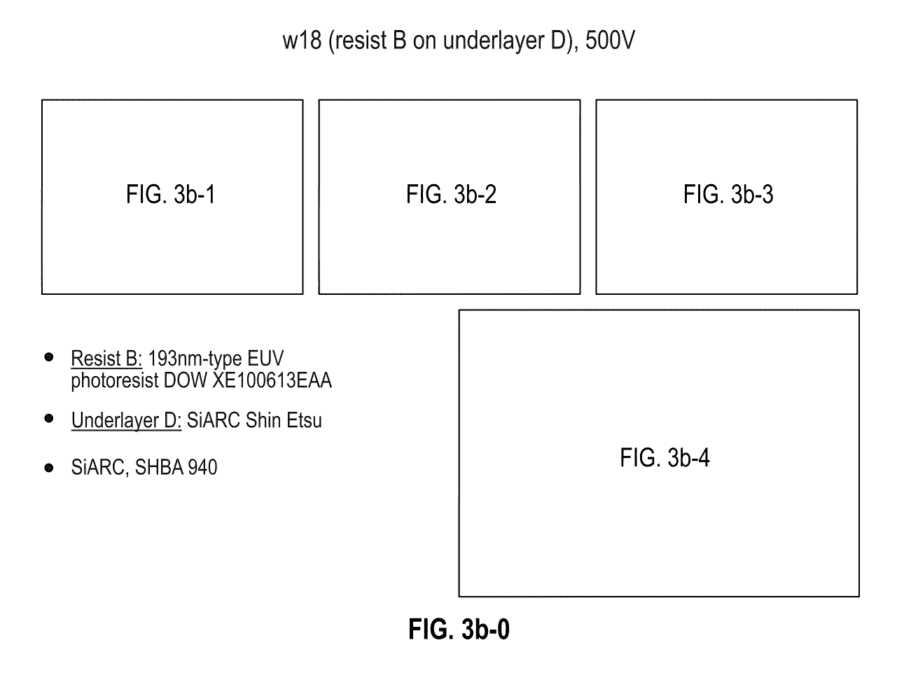

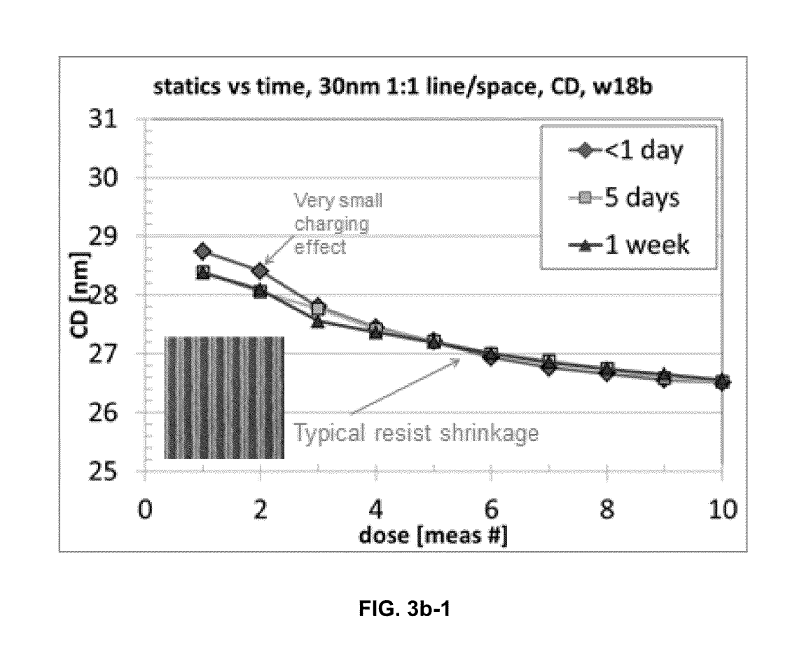

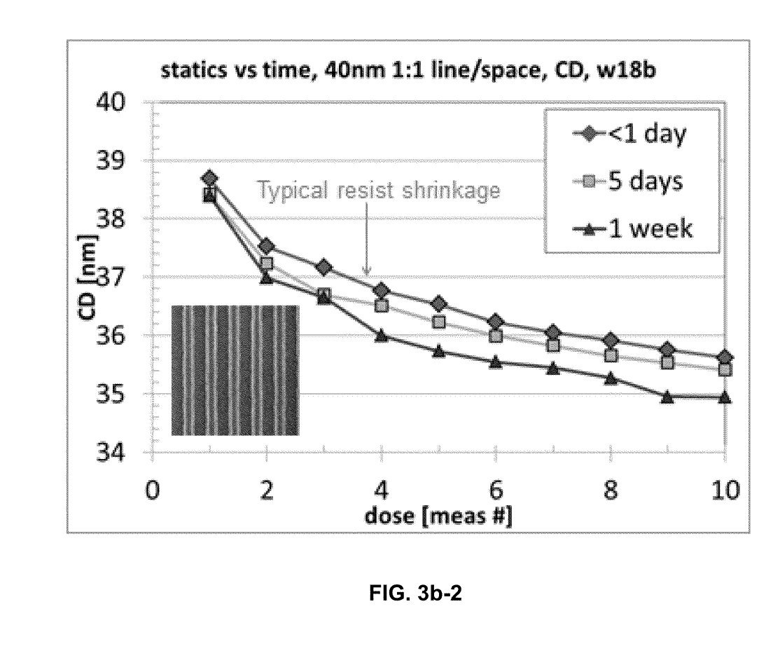

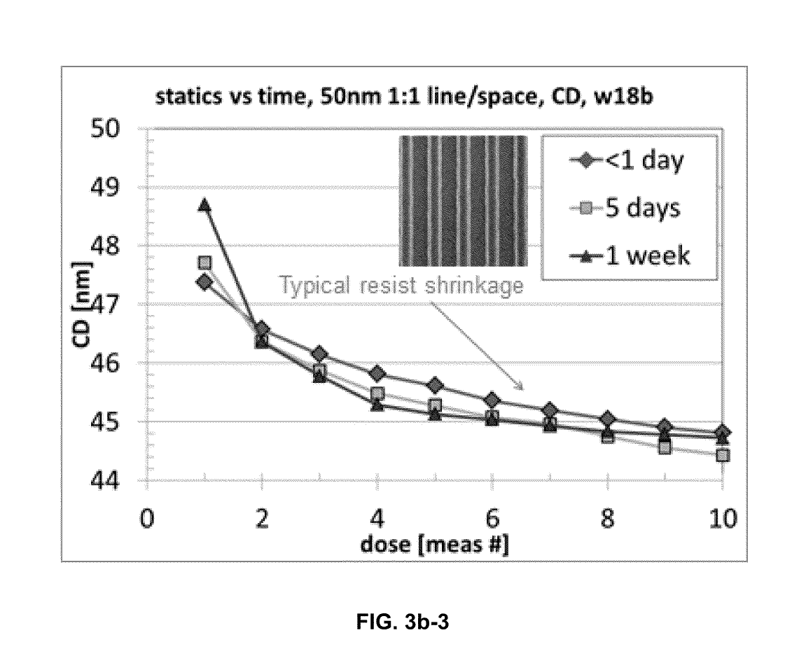

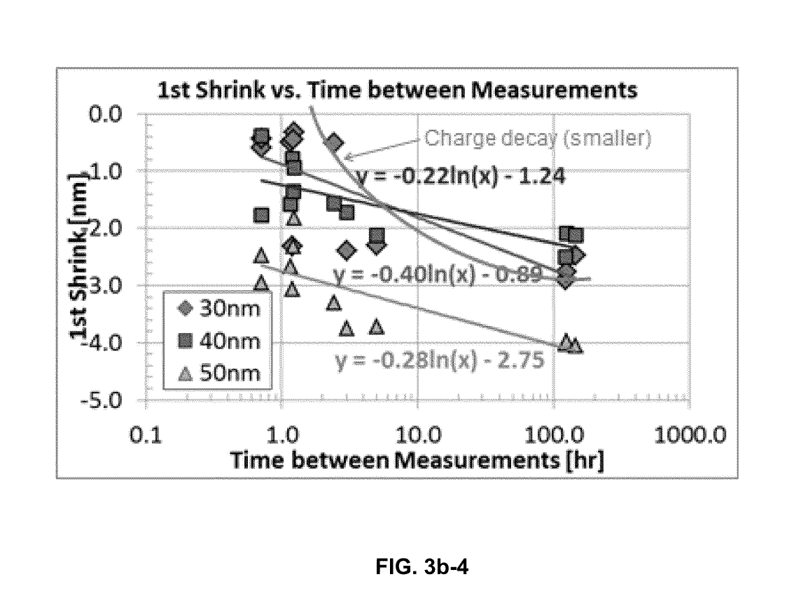

FIGS. 3a-0 to 3a-4 show charging behavior for sub-30 nm EUV resist features in the CD-SEM when the underlayer is an organic underlayer (Underlayer E is OrganicARC or “OrgArc”). FIGS. 3a-0 to 3a-4 show the difference in charging mitigation (Organic ARC versus the SiARC; SiARC has an arrow showing the very low charging).

FIGS. 3b-0 to 3b-4 show that improved charging behavior was observed for sub-30 nm EUV resist features in the CD-SEM when the underlayer is SiARC (Underlayer D is SiArc).

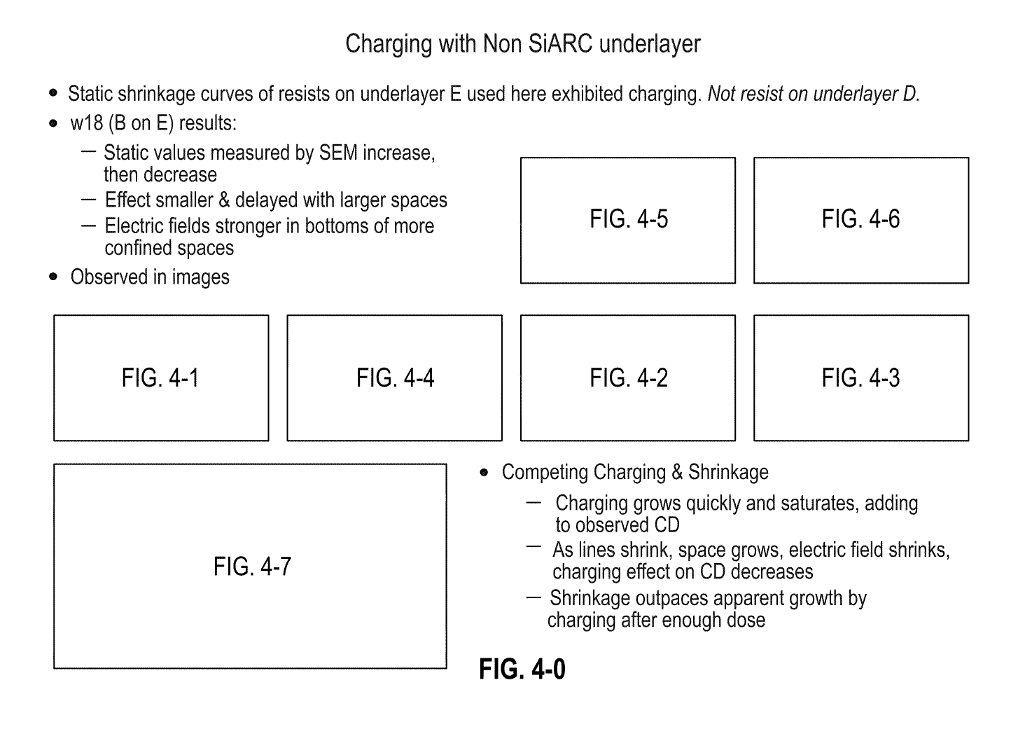

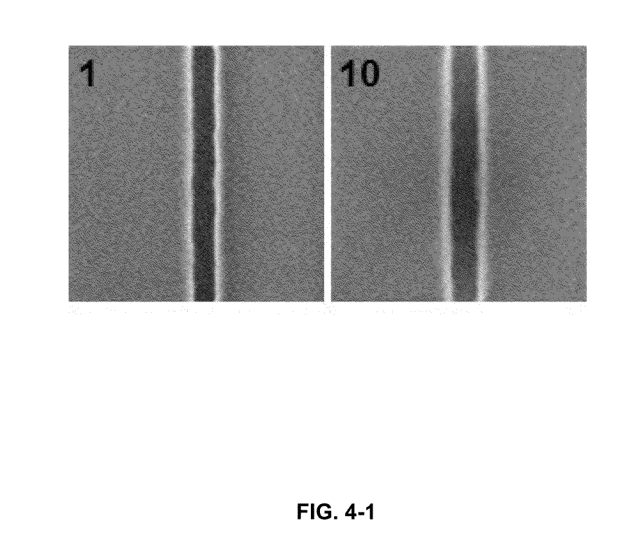

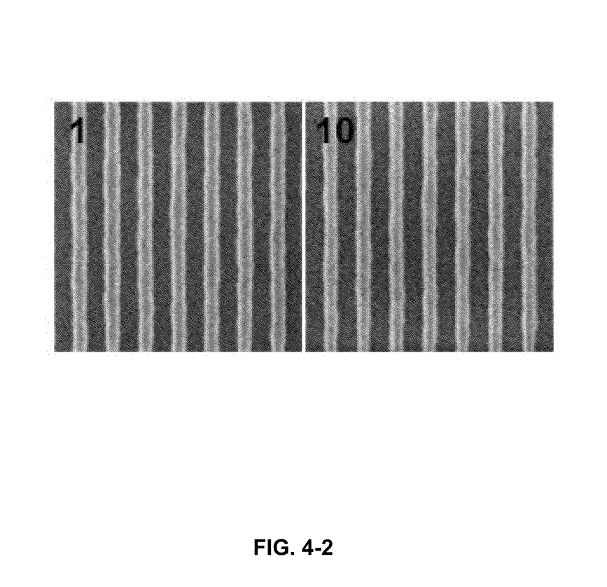

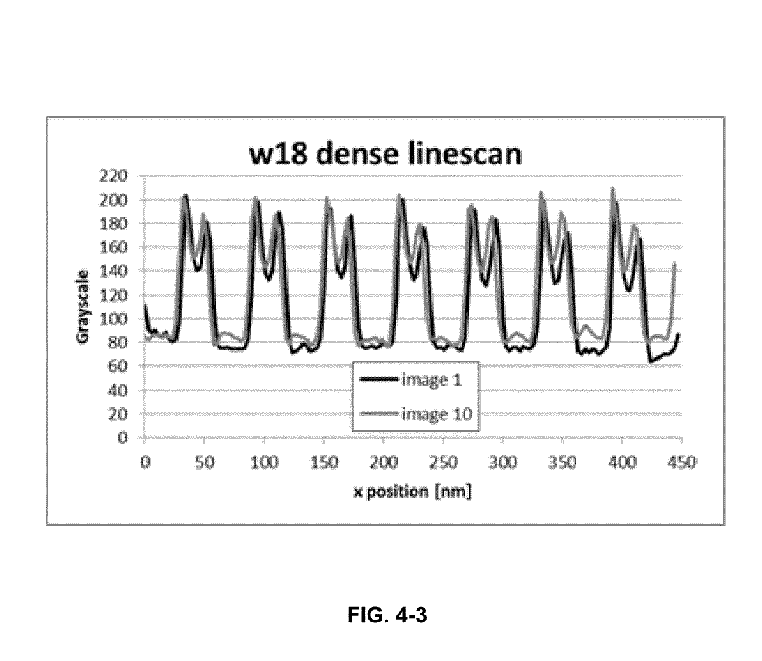

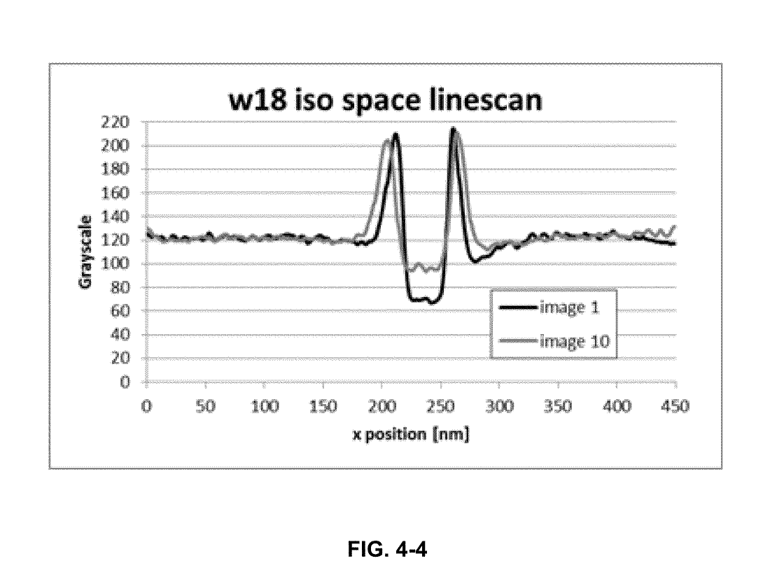

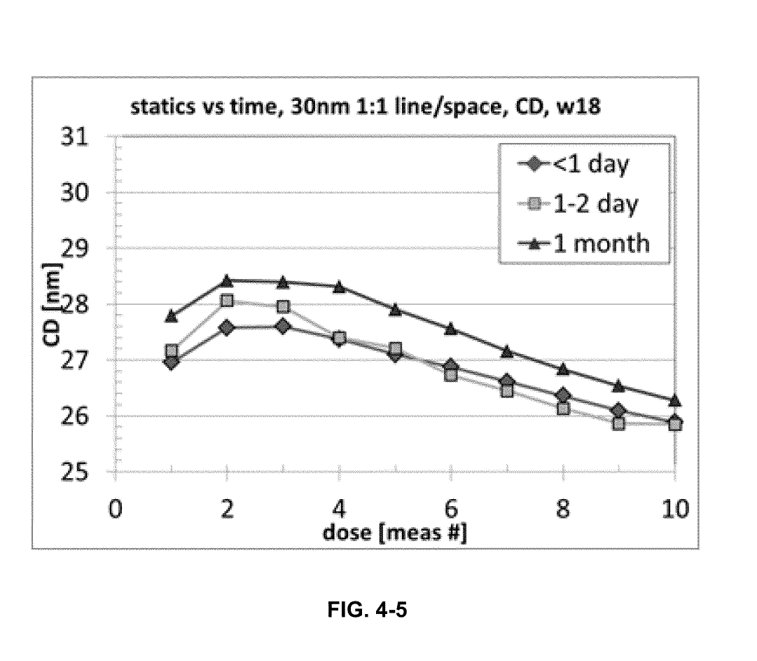

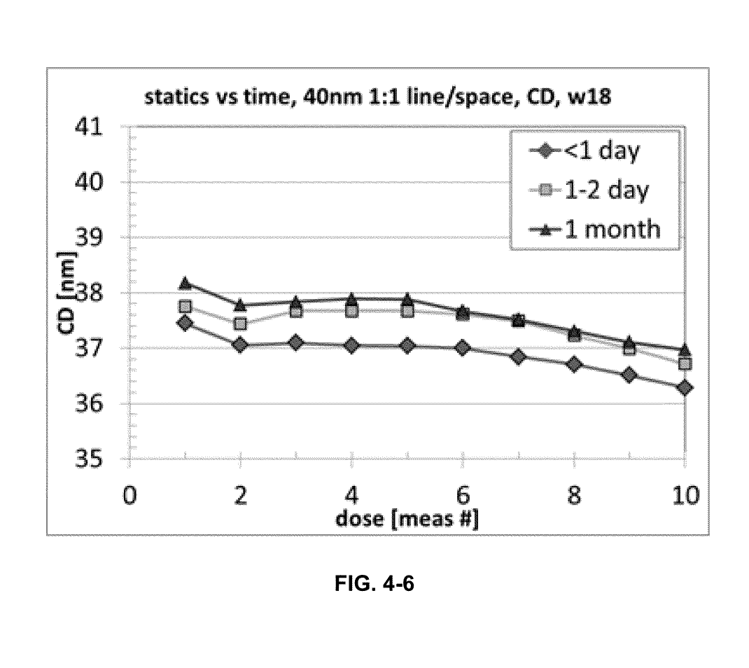

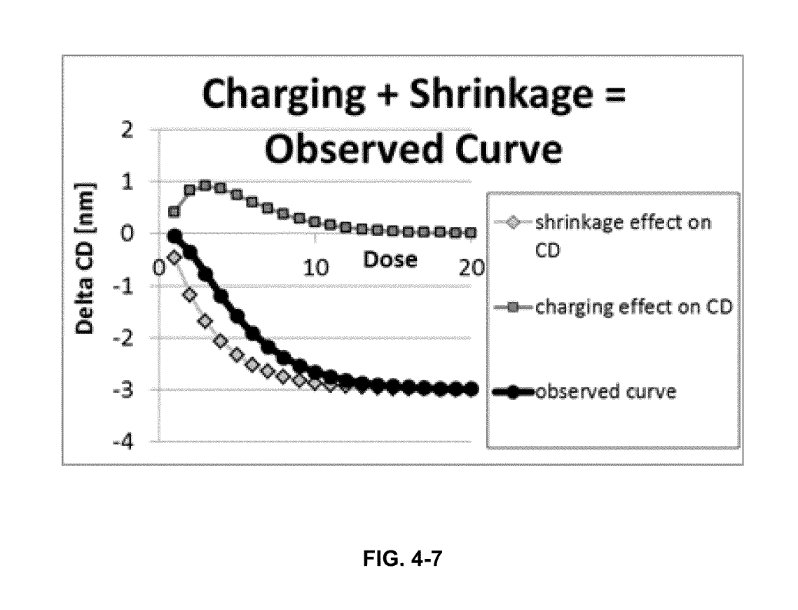

The charging behavior seen typically is clearly shown on the plots for the materials identified as the organic underlayer (OrganicARC or “OrgArc”). (FIGS. 4-0 to 4-7). This is typical behavior seen when evaluating samples in the CD SEM not coated on SiARC (e.g., coated on an organic antireflective coating, on pure silicon, etc.). FIGS. 4-0 to 4-7 also show charging behavior, and highlight the impact on the critical dimension (CD) measured. It can be seen that with respect to line edge roughness, the plots in FIGS. 4-0, 4-1 and 4-2 show photoresist lines measured (1 time then 10 times) and they depict how the CD changes, e.g., grows, after multiple measurement. The plots in FIGS. 4-1 and 4-4 show an overlay of signal take after 1 measurement and overlayed on the 10 measurement signal (highlighting the change post multiple measurement).

In summary, improved charging behavior was observed for sub-30 nm EUV resist features in the CD-SEM when the underlayer was SiARC (FIGS. 3b-0 to 3b-4) rather than OrganicARC (FIGS. 3a-0 to 3a-4 and FIGS. 4-0 to 4-7). Using the same photoresists, charge buildup was large when using OrganicARC as an under layer, and minimal to non-existent when using SiARC as an underlayer.

### 6.2. Example 2

### SEM Metrology of Photoresist Shrinkage in EUV Lithography of an Integrated Circuit

Charge build up is an important systematic uncertainty source in critical dimension-scanning electron microscope (CD-SEM) metrology of lithographic features. In terms of metrology gauge metrics, it influences both the precision and the accuracy of CD-SEM measurements. Minimization or elimination of charge build up is desirable, yet elusive. This error source plays a significant role in the accuracy of CD-SEM metrology on polymer materials, especially as EUV lithography (EUVL) becomes a preferred lithographic method for producing integrated circuits.

In this example, a silicon-comprising under layer, a silicon-comprising under layer comprising a SiARC (SHBA 940, Shin Etsu, Tokyo, Japan) is used to reduce charge buildup during CD-SEM metrology of static and dynamic shrinkage behaviors of various EUV photoresists. The use of the silicon-comprising under layer decreases charge build up and allows precise SEM metrology of the shrinkage behavior of the photoresist. Static shrinkage behaviors are then tested for compliance with the SEMATECH shrinkage model [5][6], and further studies confirm whether or not dynamic effects can be measured. Secondary trends in dynamic shrinkage are also evaluated, including how dynamic shrinkage varies with electron beam energy, activation dose, feature size, and other parameters.

6.2.1. Introduction

Charge build up and photoresist shrinkage are important systematic uncertainty sources in critical dimension-scanning electron microscope (CD-SEM) metrology of lithographic features in integrated devices. In terms of metrology gauge metrics, both these phenomena influence precision and accuracy of CD-SEM measurements. In addition, photoresist shrinkage is locally damaging to the sample Minimization or elimination of charge build up and photoresist shrinkage are desirable, yet elusive. Because these error sources introduce errors into CD-SEM metrology on polymer materials, working around and/or avoiding these errors issue is desirable.

Many studies have demonstrated the primary effect of electron landing energy on both KrF (248 nm) and ArF (193 nm) resist line shrinkage. Mitigation of line slimming has been primarily focused on the influence of probe current beam blanking, acquisition time and measurement magnification. Bunday et al., [4][5][6] have developed a model that determines the stability of CD performance, under SEM measurement, in static measurement mode. This technique has previously been used only for measurement of an ArF photoresist material.

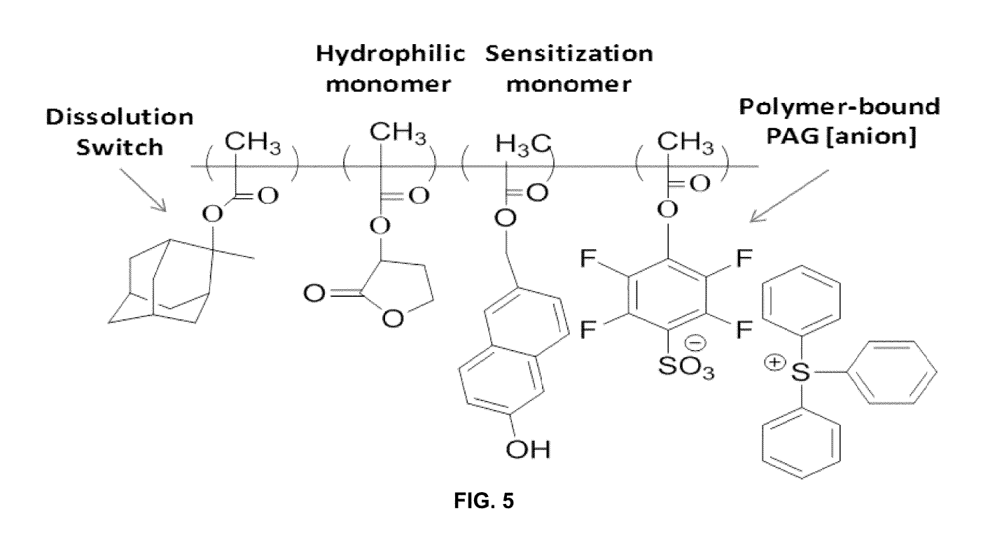

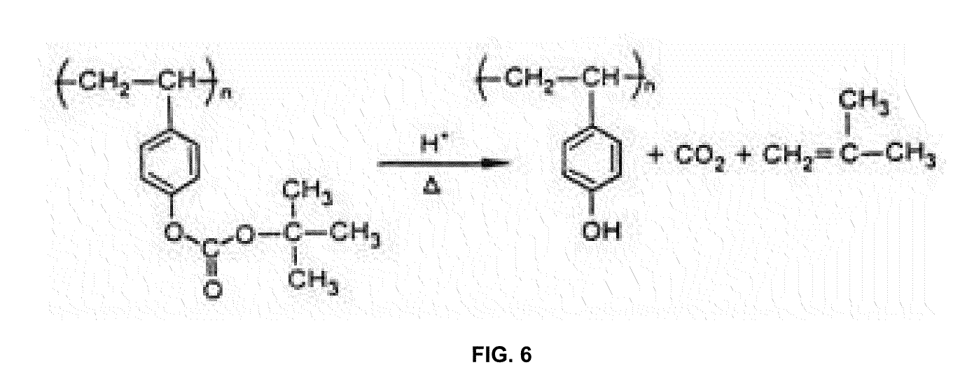

To meet the requirements of the 22 nm node and beyond, the semiconductor industry is pursuing EUV imaging at 13.45 nm. Therefore, this model is now being tested using resist materials targeted for EUV exposure. Interestingly, the evolution of photoresist chemistry from KrF to ArF and now EUV has not resulted in fundamentally new resist chemistry. Specifically, the same polymers, photo acid generators (PAGs), and dissolution inhibitors can be used with slight adjustments easily made by the skilled artisan to EUV resist formulations. The most positive recent results have been seen with photoresists that have the PAG chemically bound to the polymer [9]. FIGS. 5 and 6 show the chemical structures of these types of polymers.

The work disclosed in this example investigates time-dependent shrinkage effects, including how the photoresist shrinkage rate varies with time from the chemical development of the photoresists, and the differences in shrinkage rates between static and dynamic load/unload cases. An underlayer of SiARC is used to reduce charge build up and improve the accuracy of SEM metrology in measuring the shrinkage. The results of these dynamic effect experiments can have far-reaching implications for the shrinkage phenomenon in general and should be especially important to photoresist makers, lithographers, and particularly CD-SEM metrologists.

6.2.2. Basic Metrology and Shrinkage Concepts and Terminology

Precision is a general estimator of the variability of a measurement process about the mean value of the test results. Metrologists usually evaluate precision to represent an error bar for measurements. Because precision is a multiple of reproducibility [10][11], to evaluate precision, repeatability and reproducibility, gauge studies are performed. Repeatability is evaluated for both static and dynamic cases. Static repeatability is the standard deviation of multiple measurements, for which measurements are collected within a short time period, all metrology factors that may influence the measurement are held constant, the measurement location is held constant, and the wafer is not unloaded from the measurement tool between measurements. Dynamic repeatability is similar, except that the time between consecutive measurements is much longer and the wafer is unloaded between measurements. Thus, the time between measurements and possibly navigation to the exact same location are the differences between static and dynamic measurements.

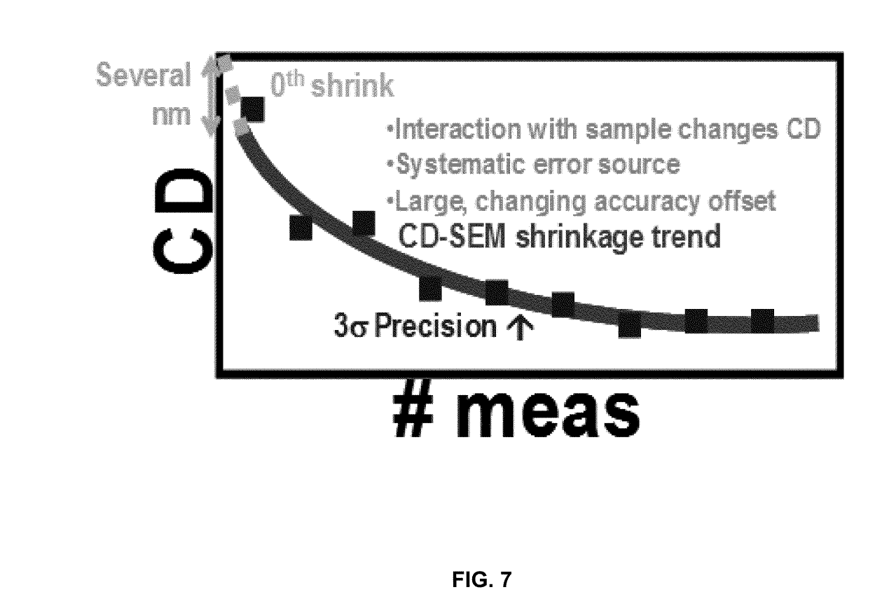

Photoresist shrinkage is the reduction in a resist feature's width due to exposure to an electron beam during imaging in a CD-SEM; it is the quantifiable result of the local damage caused by electron beam irradiation of the resists. In studying photoresist shrinkage, static repeatability is the test most metrologists perform, because along with evaluating randomness of the metrology, it allows the trend of the measurements due to sample damage to be observed. This is often called the “shrinkage trend” or “shrinkage curve”; an example is shown in FIG. 7. Practically, this data is collected with a “hammer test,” in which the same measurement site, i.e. the same exact segment of a photoresist feature, is subjected to many consecutive measurements that include a specified quantity of dose of electron flux. This test is documented elsewhere [1].

The naming convention of a few important quantities related to these measurements and shrinkage trends also need to be defined. When measuring a shrinkage curve, the widths are the apparent widths as reported by the CD-SEM. Therefore, the first CD means the apparent CD reported by the first CD-SEM measurement, i.e. after one electron beam dose of the site. The second CD means the SEM-reported CD measurement at the second CD-SEM measurement of the site. The CD of virgin photoresist, with no electron beam-induced shrinkage, is obviously not known by the CD-SEM, but is some value that might be measured by another technique that does not cause photoresist to shrink, such as CD-AFM, as demonstrated in another work [3]. This pre-shrink CD value is called the 0th CD.

In short, “Shrinks” are defined as differences between these apparent measurements by CD-SEM. 0th shrink is the shrinkage that occurs during the initial e-beam dosing of a site, and is unknown empirically, unless known from another method. first shrink is the difference between the first and second CD measurements by the CD-SEM, and second shrink is the difference between the second and 3rd measurements by CD-SEM, etc. Total shrink refers to the difference between the first CD-SEM measurement and the last CD-SEM measurement of a long series.

6.2.3. Charge Build Up and Photoresist Shrinkage Reduce the Accuracy of CD Metrology

Addressing the constant need to reduce the dimensions of integrated circuits, lithography has been forced to change over time to meet Moore's Law. Successful printing of shrinking geometries depends on the implementation of advancements in optical lithography and reticle technology for patterning. Resolution enhancement techniques (RETs), such as reduced wavelengths, improved numerical aperture (NA), advanced scanner illumination schemes, and reticle phase shifting, all play a role in improving the lithographic resolution of the critical dimensions (CDs) of features.

Scanning electron microscopy (SEM) is the most widely available and cost-effective method for measuring critical dimensions of lithographic features. As discussed above, a major problem in employing SEM for CD metrology is that as the target feature size decreases, the impact of charging increases. The buildup of surface charge on surface or feature of interest caused by the electron beam of the SEM will thus cause gross image distortion or image obliteration. Such image distortion or obliteration poses a significant problem in the manufacture of integrated circuits.

Furthermore, with each new lithographic generation, new photoresists have been formulated and used. With KrF (λ=248 nm) and ArF (λ=193 nm) lithography and in upcoming extreme ultraviolet (EUV) lithography (λ=13.45 nm), chemically amplified resists (CARs) are challenging CD-SEM metrology due to resist shrinkage (i.e., line slimming) See FIG. 7 for an illustration.

It is well understood that the electron beam (e-beam) exposure is initiating the chemical amplification mechanism of the photoresist (effectively exposing the dark field to electrons) causing a loss in the volume in the unexposed film (a sort of e-beam induced flare). [2][3][4][5][12].

Unless resist chemistries change, shrinkage will continue to reduce the accuracy of SEM metrology, as has been reported [2]. Thus, for the metrologist, the mechanics of the shrinkage trend and ways to predict and/or minimize it become a key interest, as resist shrinkage introduces significant measurement uncertainties.

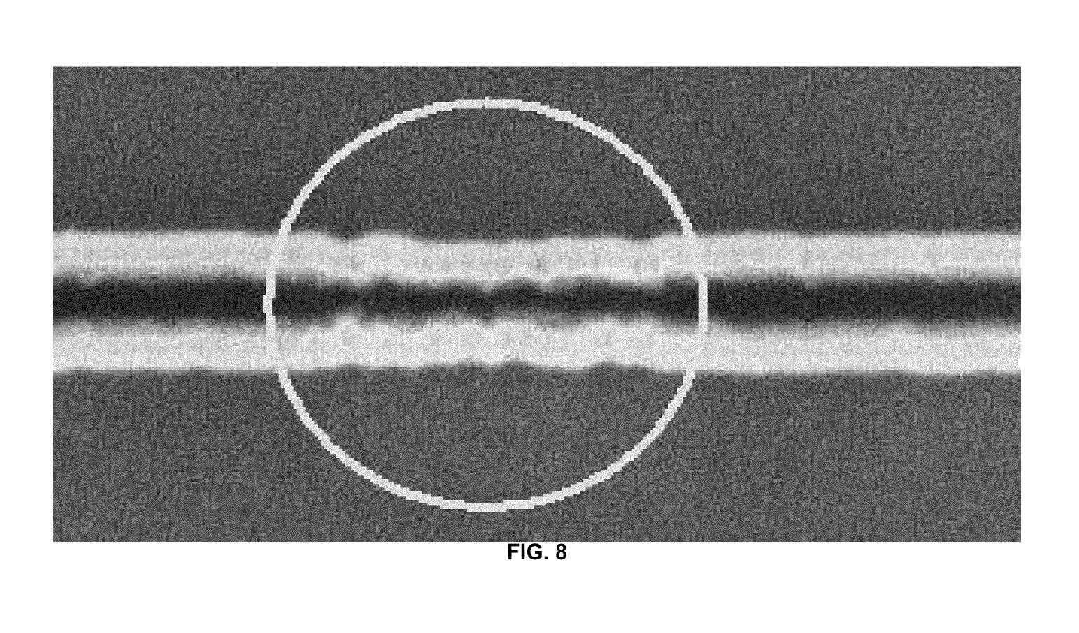

Shrinkage effects are very dependent on both the formulation of the photoresist and the CD-SEM measurement conditions. Non-optimized conditions can cause several nm of measurement uncertainty. The most important consequence of this initial (0th) resist shrinkage, during the first dose by electron beam, is the resulting CD bias which is an unknown systematic source of error when evaluating tool uncertainty, i.e., a bias to accuracy correlation [1]. When a metrologist correlates a tool under test with a reference tool, he (or she) ideally performs a Mandel regression. Metrics for accuracy are thus determined, including slope, offset, and total measurement uncertainty (TMU); the resist shrinkage during the first e-beam exposure (the 0th shrink) becomes a component of the offset or slope terms. These measurements are becoming critical as they form the basis of an accuracy offset in such calibration activities, particularly as they relate to optical proximity correction (OPC) setup and verification by CD-SEM, for which CDs are entered as physical quantities into physical models that assume accuracy. Subsequent measurements (second, third, etc.) also induce shrinkage, although not as much as the shrinkage from the first dose. The CD trend acts roughly as an exponential decay with dose, in that it mathematically dominates the calculation of 3σ precision estimations, such that trend removal is needed to determine the true random component of the uncertainty. The random component is of greatest importance in manufacturing, because a production wafer is usually measured only once. This has led many in the industry to define precision as a measure of the randomness of a series of measurements about a systematic trend; the trend is established by repetitive measurement and averaging of numerous sites. Finally, some processes are becoming sensitive to pattern damage after etch due to shrinkage at the measurement sites. The observed pattern damage is impacting the electrical performance of the final product. Therefore, methods to reduce shrinkage must be pursued whenever possible. See FIG. 8 for an example of damage after SEM exposure (image in the circle is post SEM exposure).

Uncertainty as defined in the International Technology Roadmap for Semiconductors (ITRS) [1][13][14] includes precision, accuracy, and matching components; all are believed to be important for the level of process control required for successful high volume manufacturing (HVM), particularly as we move through and beyond the 22 nm and 16 nm technology nodes. As a consequence, metrology strategies at some of the most advanced IC manufacturers include controlling tool-to-tool matching of their production CD-SEMs for all main production layers, including photoresist layers, because matching is the other key metrology uncertainty component that can be influenced by shrinkage effects when photoresist samples are used. This facet of matching is rigorously explored in another work [7]. The main CD-SEM conditions that affect static resist shrinkage are the accelerating voltage and dose of the e-beam. Dose is defined here and in [1] as the charge deposited per unit area, which depends on beam current, e-beam exposure time, and irradiated area, such that D=I·t/A.

Production metrologists who use the CD-SEM for resist measurements often choose a low dose, low voltage strategy to optimize raw precision and minimize the accuracy offset and damage carryover after etch. Alternatively, they may use a high dose, high voltage strategy to achieve repeatable shrinkage to optimize the precision about the known trend.

Over the years, many other works have explored photoresist shrinkage. Those studies have all concentrated on static measurements, studying repeated electron beam doses on a resist target to quantify how much the target changes. This is important, as it demonstrates the dependence of shrinkage on electron beam dose for the various SEM beam conditions, which is the main component of shrinkage and the one that can be modeled or extrapolated to solve 0th CD.

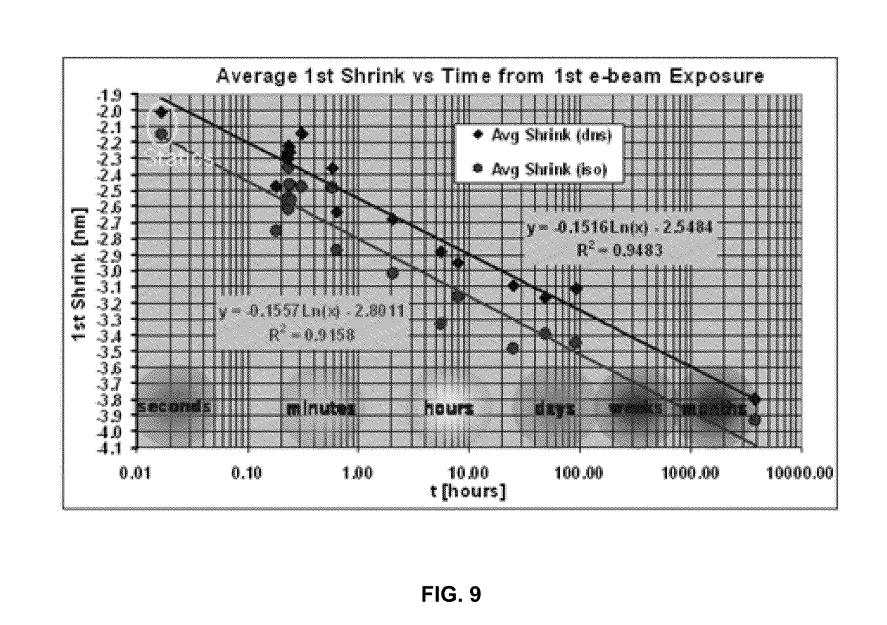

However, another major consideration of shrinkage that is only beginning to be understood is dynamic shrinkage effects, where the time between consecutive measurements, age of the photoresist, and possibly vacuum cycling are now being recognized as significant variables. FIG. 9 shows the dynamic shrinkage effect, in which photoresist features begin to shrink due to first exposure to the electron beam and continue to shrink by a kinetic chemical reaction that was activated by the electron beam [7][8]. In real life, accuracy or matching experiments that require two tools to be correlated to each other, the wafer targets must be transferred between tools for different measurement recipe runs and/or over significant time delays, meaning that these are, by definition, dynamic loading situations. Long-term precision experiments also involve dynamic time delays and load/unload activity. Therefore, to better understand accuracy, long-term precision and matching with photoresist targets, we must understand the dynamic shrinkage effects, especially the influences of time between development of the wafer and the first CD-SEM measurement and of time between consecutive measurements of the same site to fully understand their influences on CD-SEM metrology uncertainty.

Previous work in the field has posed some questions that need to be answered to better understand these dynamic effects [7][8]: First, does this phenomenon occur in other CARs, and if so, how is it impacted by varying the formulation? We must confirm that this is a widespread phenomenon with other CAR formulations, not just an isolated incident with that particular resist (although the resist in [7][8] is a typical, mainstream immersion ArF resist product). Second, the original effect was observed with a 300 V beam; how does it behave at other beam energies? Third, how does the effect vary with feature size?

6.2.4. Materials and Methods

In this example, the static and dynamic shrinkage behaviors of EUV photoresists are surveyed. EUV photoresists represent the future of EUV photolithographic materials. A design of experiment (DOE) of three different EUV photoresist formulations undergoes systematic static and dynamic shrinkage experiments for varying feature sizes, to look for trends in shrinkage behavior that answer the questions above. One of the photoresists is the baseline SEMATECH EUV photoresist, and with it, the variation of the dynamic effect with beam energy is also explored.

All of the EUV lithography and CD measurements were performed at the SEMATECH Resist Materials Development Center (RMDC) located at the College of Nanoscale Science and Engineering (CNSE).

CD-SEM Measurement DOE and CD-SEM Experimental Recipes

This work aimed to explore static and dynamic shrinkage effects for various types of EUV photoresists, including the effect of resist age on static shrinkage, resist age and time between measurements for dynamic shrinkage, and the dependence of dynamic shrinkage on resist formulation, SEM beam voltage, and feature size. A DOE similar to the one in the previous work [7][8] was adapted to enable running the test protocol on a single wafer for a given material stack to minimize the lithography and improve the convenience of handling single wafers, enabling faster CD-SEM recipe execution. We used single wafers, which eliminates wafer-to-wafer variation as a component of these results.

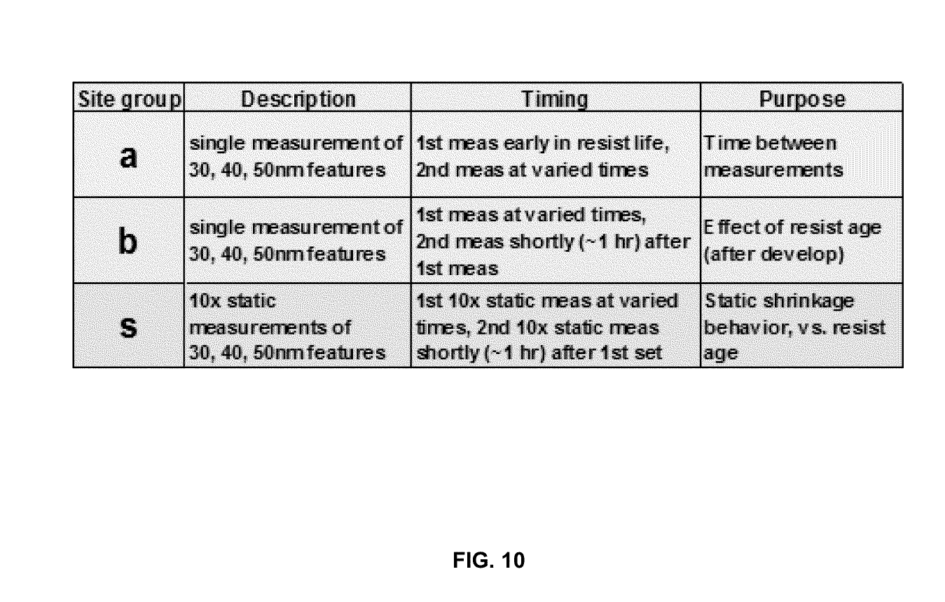

The CD-SEM experimental recipes included three site groups, each with its own purpose. Each site group included three different 1:1 dense linewidth features of varying nominal CD values. FIG. 10 explains these site groups.

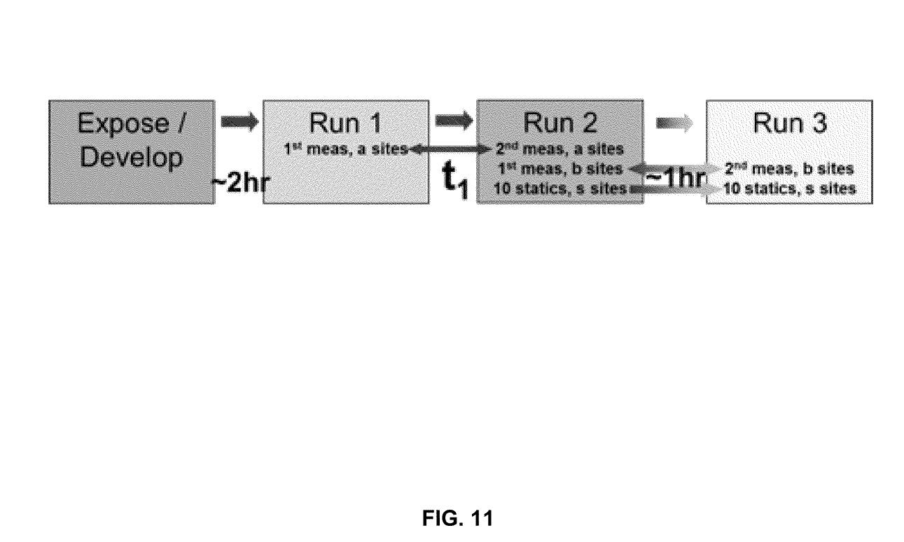

The site groups are the basic “building blocks” of a larger set of CD-SEM recipes. Each die is visited three times, with some of the site groups measured each time. FIG. 11 presents how these site groups within a die are measured at different times.

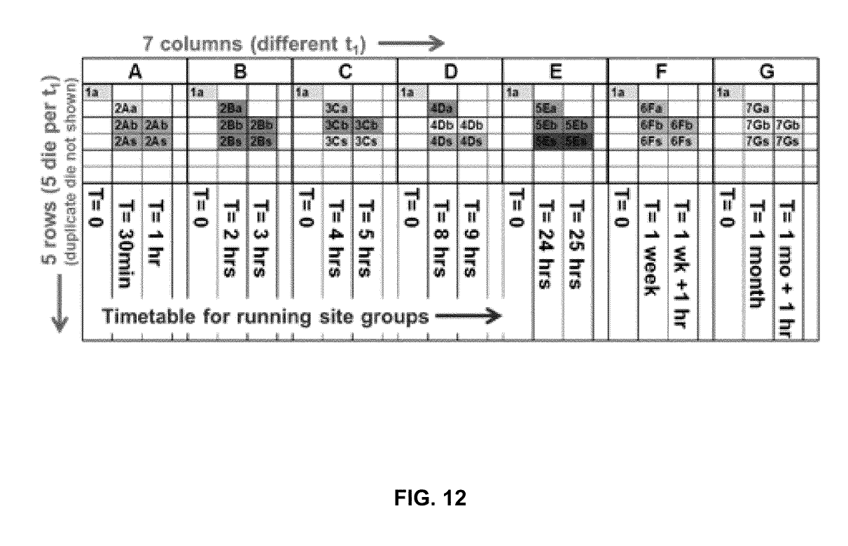

To execute this strategy, a group of pre-designed modular CD-SEM recipes were written, with each site group “copied exactly” to visit different die, at different times, for different appropriate site groups. Once the wafer completes lithographic processing, the time clock starts. As soon as CD-SEM time is available, the wafer undergoes the initial CD-SEM recipe, which includes the first measurement of site group a for all die of the wafer; this was typically around 2 hours after the wafer left the lithocell. It is shown as “T=0” in the timetable in FIG. 12. Later recipes are run by the timetable in FIG. 12, although strict adherence to the timetable is not vital, just a guideline for adequate sampling of the time range (when we graph the results, any variations of time from the plan will just move points along the same curves). t1 is the main variable in the DOE, defined as the time after the initial SEM recipe run for all die of site group a. Each column of the wafer is used for a different t1, so that the next recipe runs visit individual columns and measure site group a for the second time, then site groups b and s for the first time. Then another recipe runs sites b and s for the second time. This repeats until all columns are completed. Timestamps for all measurements are recorded, and the CD-SEM's and lithocell's clocks are confirmed to be synchronized. Between recipe runs, all wafers were stored in the same front opening unified pod (FOUP), in typical storage conditions for a class 1 fab with good environmental controls for temperature, humidity, air purity, defectivity, and background light spectrum.

In summary, the purpose of site groups a and b was to explore shrinkage due to dynamic sources. Each site was measured twice, i.e., once in each of two consecutive recipe runs. Some sites began measurement at different resist ages, some sites had different durations between different measurements, and some sites began measurement after either one or two vacuum load cycles. Differences in the first and second measurements of these sites, along with the difference in times, are used to sample the dynamic effect. The value of the first CD measurements as a function of timestamp confirms the stability of the CD of virgin photoresist lines with age. The purpose of site group s was to collect the static shrinkage data to compare with the dynamic data from the other site groups. Since the static measurements began after a delay, the variation in static measurement behavior as a function of resist age is explored. In continuing this collection of static measurements into the last round of recipes, we also collected data to see the effects of a combination of static and dynamic measurements, although those results are not shown here. These static shrinkage curves will also be fit by the SEMATECH shrinkage model to verify a given photoresist/SEM condition combination complies with the model, which is strong confirmation that the photoresist shrinks similarly to other photoresists. Through the solved model parameters, more insights can be drawn.

CD-SEM Metrology Details

The set of SEM recipes created for these studies was run identically for all wafers. All conditions, parameters and measurement target setups were carefully held constant, except beam energy; with the baseline resist A, 300 V and 800 V were used in separate experiments, in addition to the standard 500 V value (this was to directly explore the influence of beam energy on the dynamic effect). The tool was a latest generation, typical CD-SEM. The CD-SEM parameters were as follows:
Ebeam=500 V
Iprobe=8 pA
300 kx→FOV=450 nm
512×512 pixels→0.88 nm square pixels
16 frames→Tintegration=0.53 s
All Pattern Recognition offsite 6000 nm & Autofocus offsite by >3000 nm
Algorithms
   CD: threshold algorithm (60%), smoothing=7, meas pt=32, sum lines=16
   LWR: threshold algorithm (60%), smoothing=7, meas pt=200, sum lines=2

Precisions for both CD and linewidth roughness (LWR) measurements of single line measurements were confirmed, after shrinkage trend removal, to be approximately 0.50 nm. When 30 nm and 40 nm 1:1 line/space targets were measured, average measurements of 5 lines were reported, and when the 50 nm 1:1 line/space targets were measured, average measurements of 3 lines were reported. Since 5 die were typically measured for all the targets, the uncertainties of various data points is averaged down by a factor of sqrt(N), accordingly. So the uncertainty for 25 line averages is 0.10 nm (applicable to the 30 nm and 40 nm linewidth measurements), and the uncertainty for 15 line averages was 0.13 nm (applicable to the 50 nm linewidth measurements). These values are directly applicable for the static measurement cases; when measurement of differences is to be reported, such as the dynamic shrinkage experiments, these uncertainties increase by a factor of sqrt(2) to 0.14 nm for 25 line averages and 0.18 nm for 15 line averages.

6.2.5. Results

Electron charging is accumulation of negative charge on a sample irradiated when it is irradiated with electron beam. Charging tends to occur in an SEM when there is poor electrical conductivity of the specimen. Specifically, when the number of electron incident to the sample is greater than the number of electrons escaping from the sample a negative charge builds up at the point where the beam hits the sample. Charging causes a range of unusual effects such as abnormal contrast and image deformation and shift.

One method used to eliminate electron charging is to coat the sample with a thin conductive film before being placed into the SEM chamber. If the sample has is electrically conductive then it may not need a conductive coating. Typical materials that have been used for coating SEM samples are carbon and gold paint.

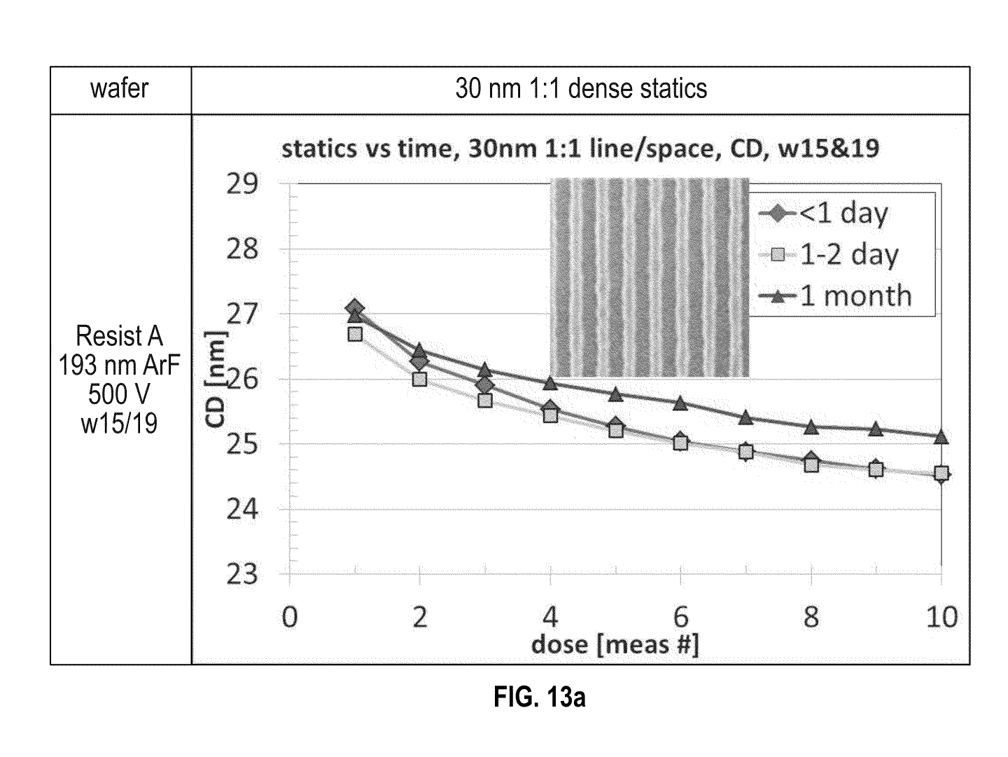

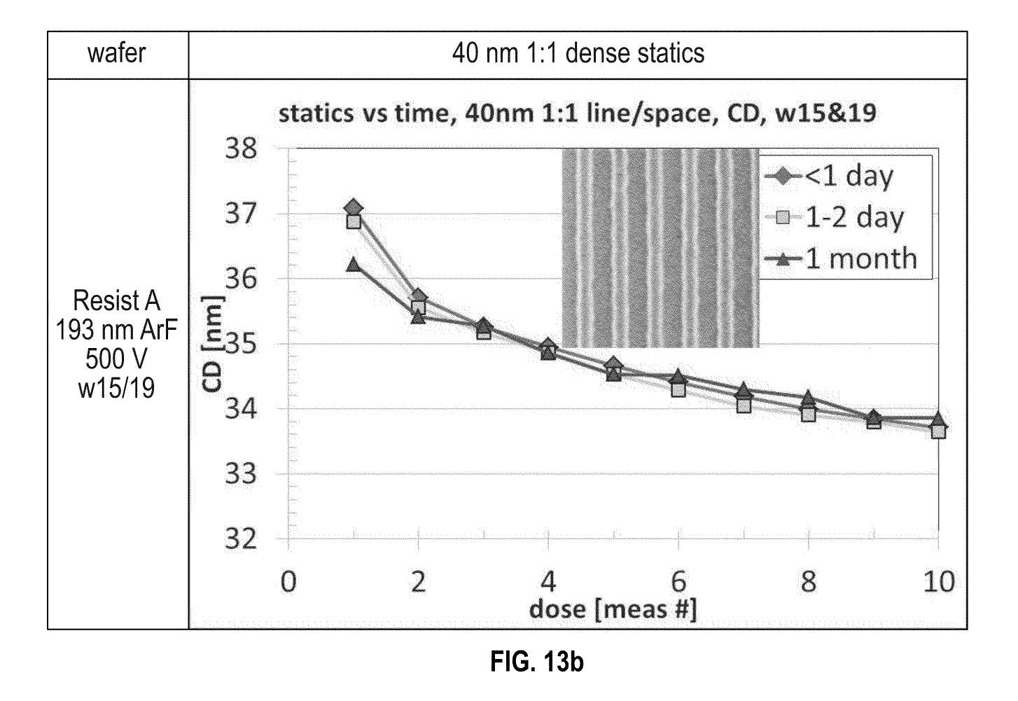

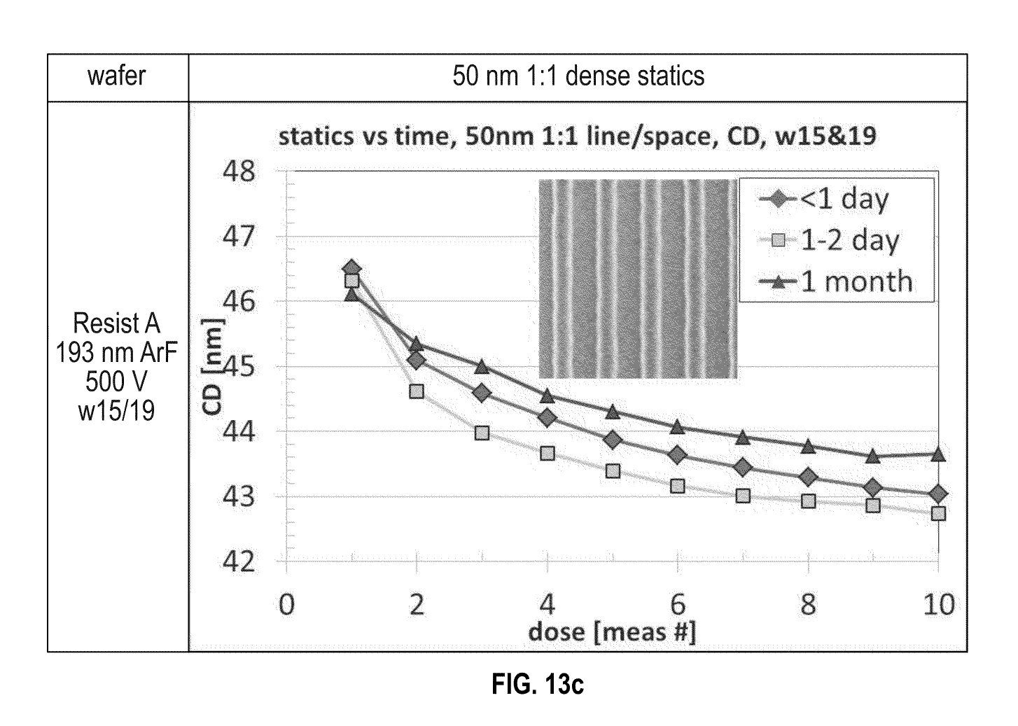

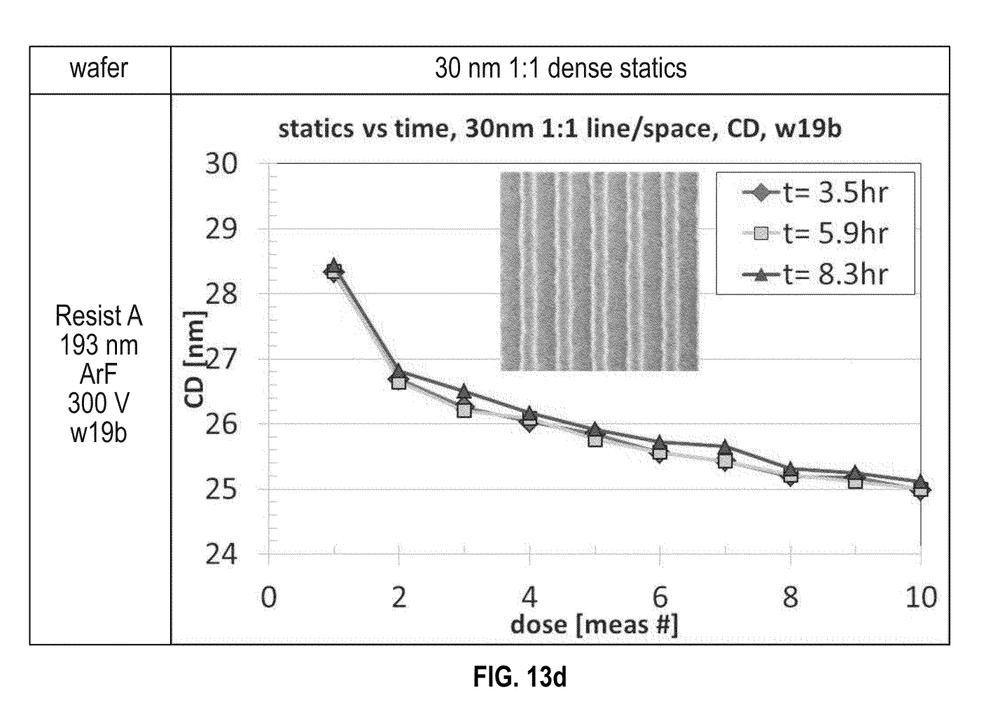

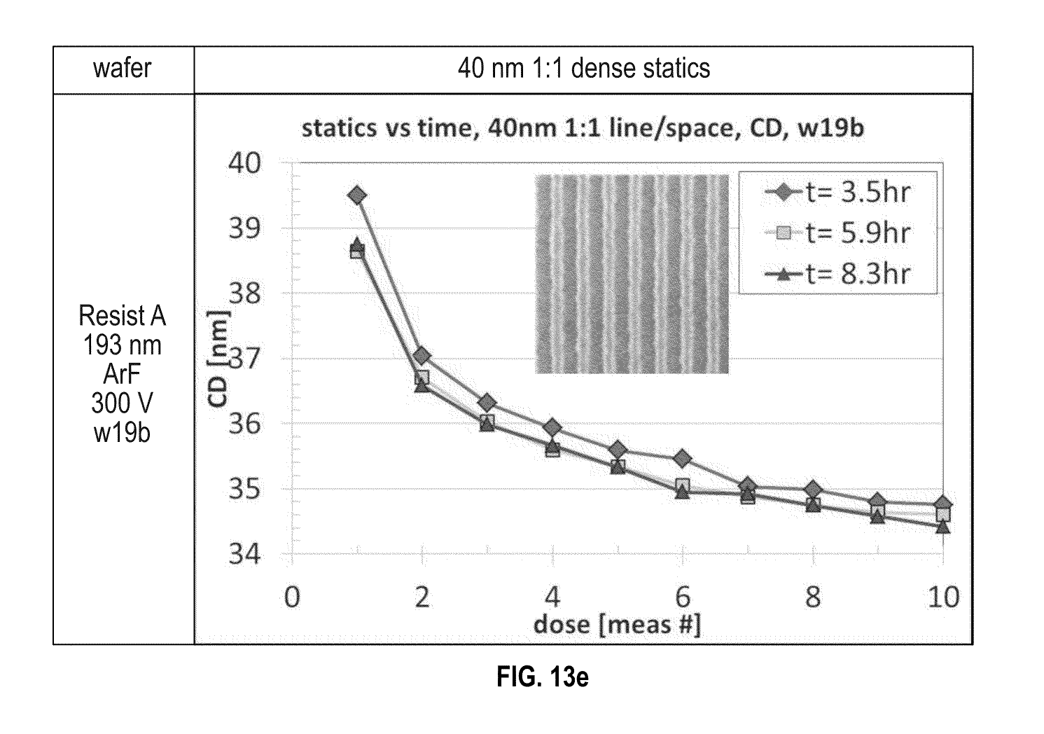

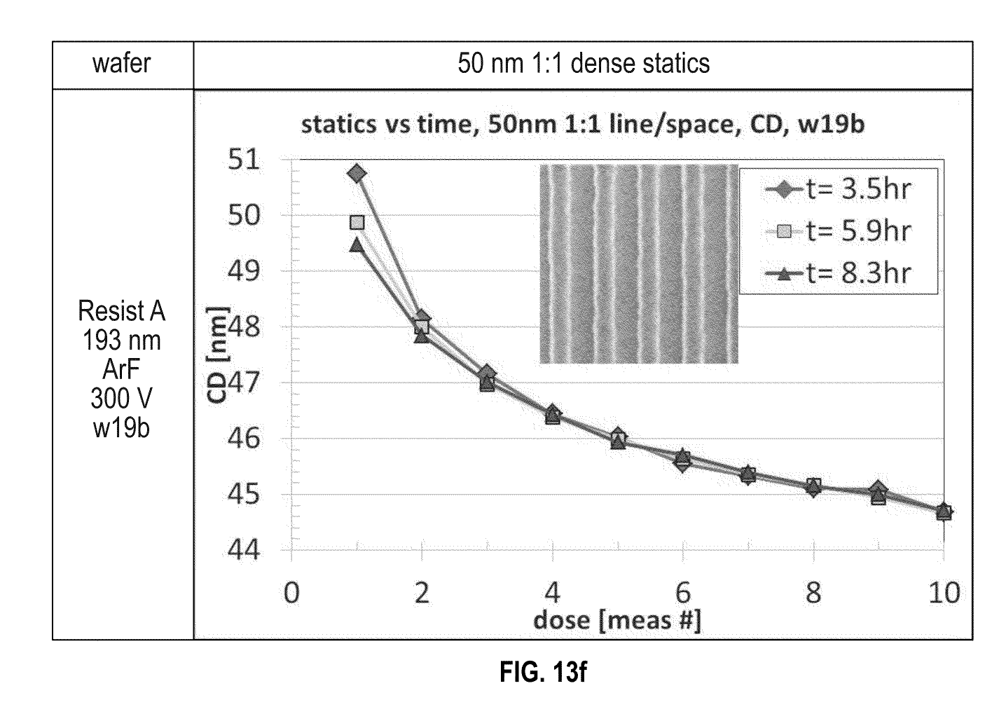

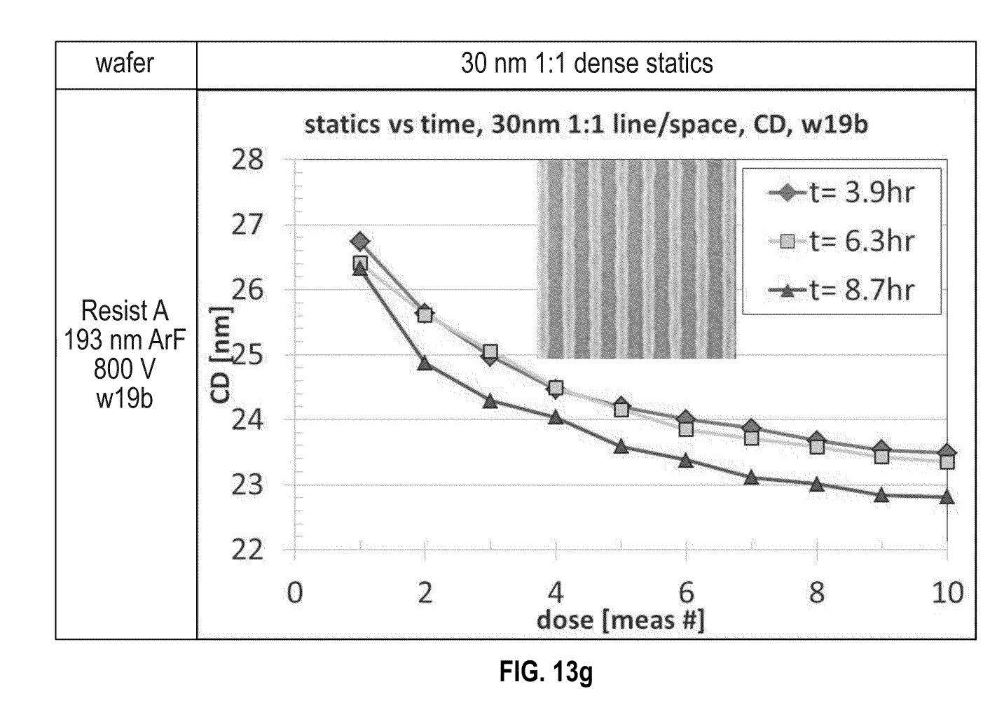

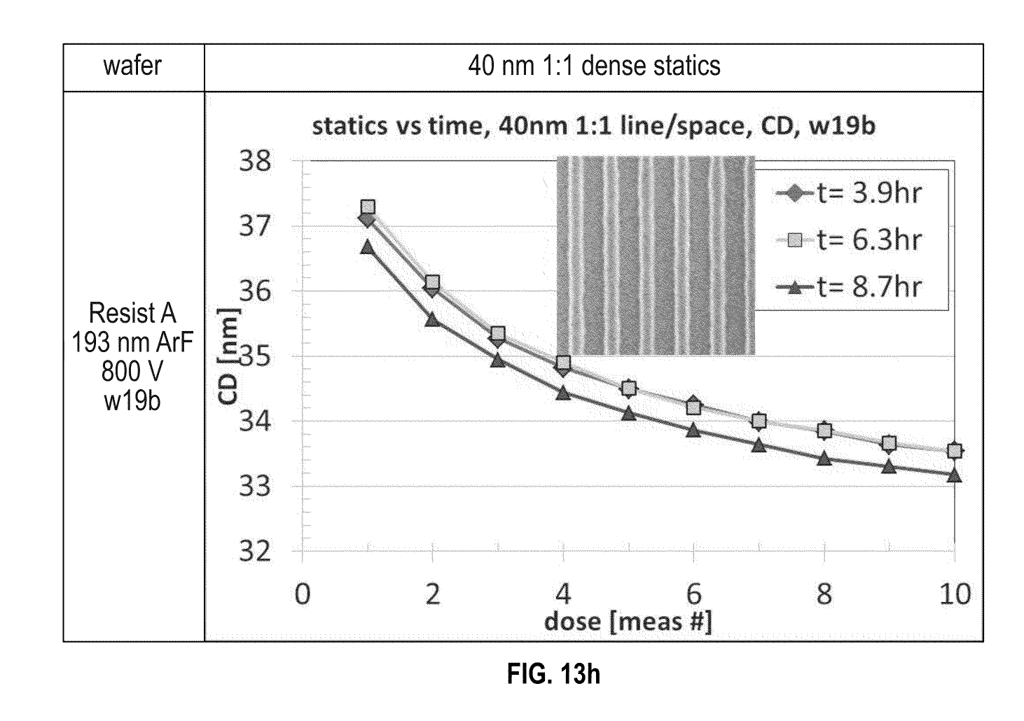

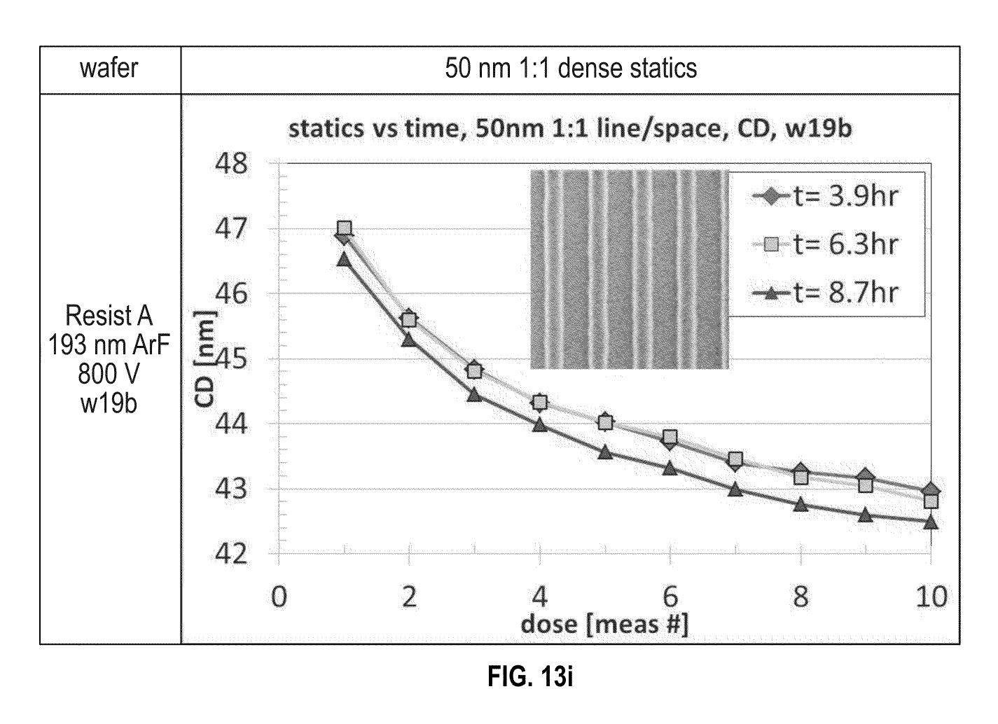

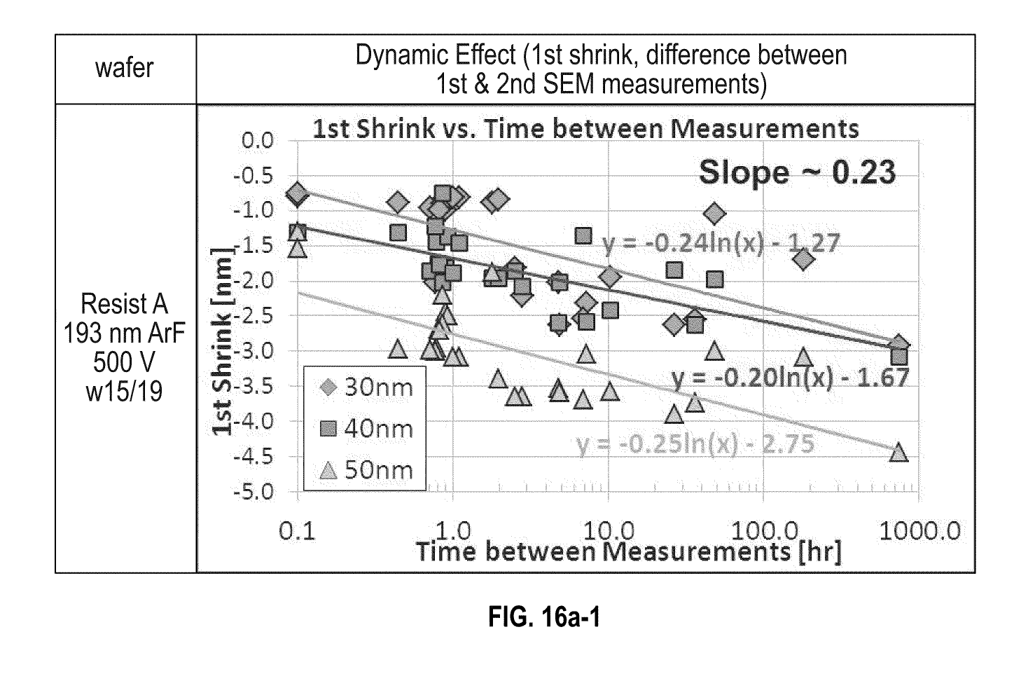

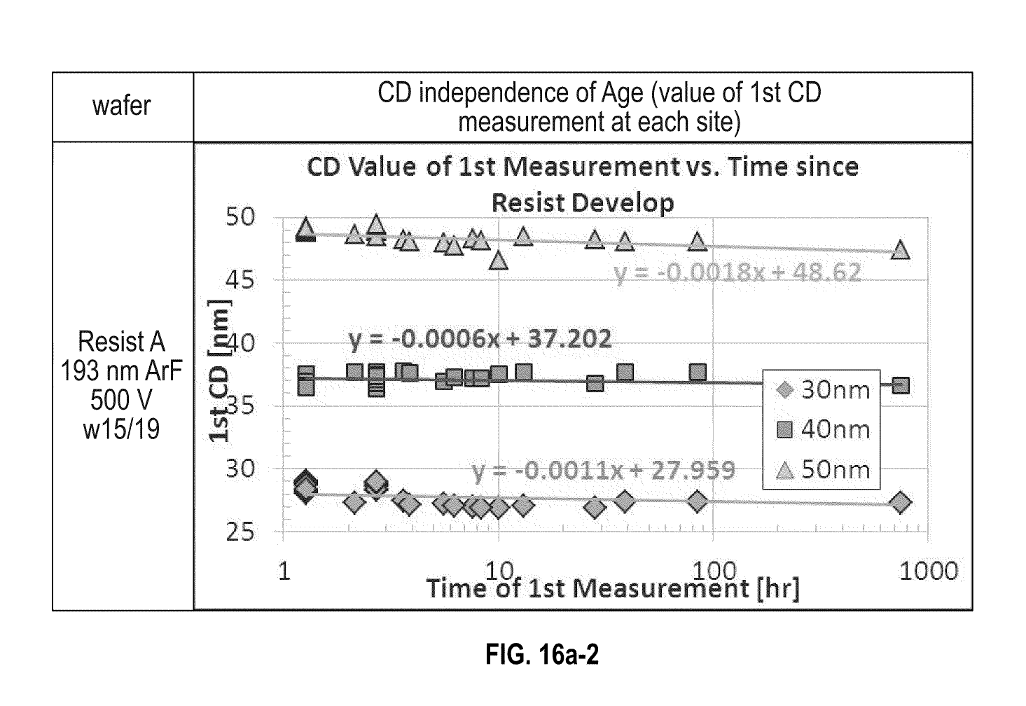

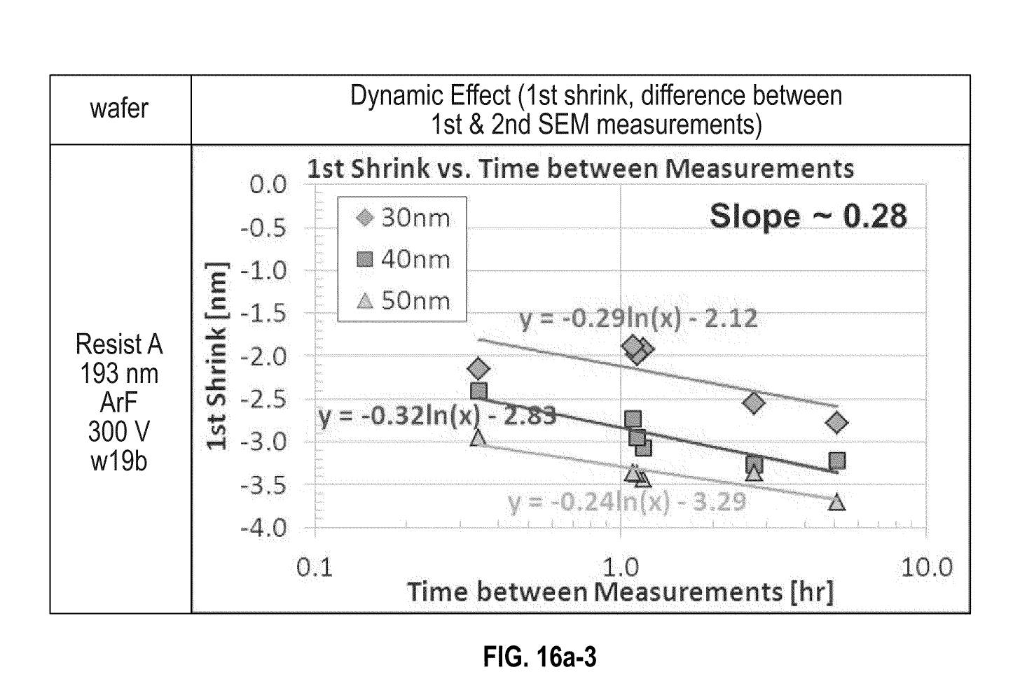

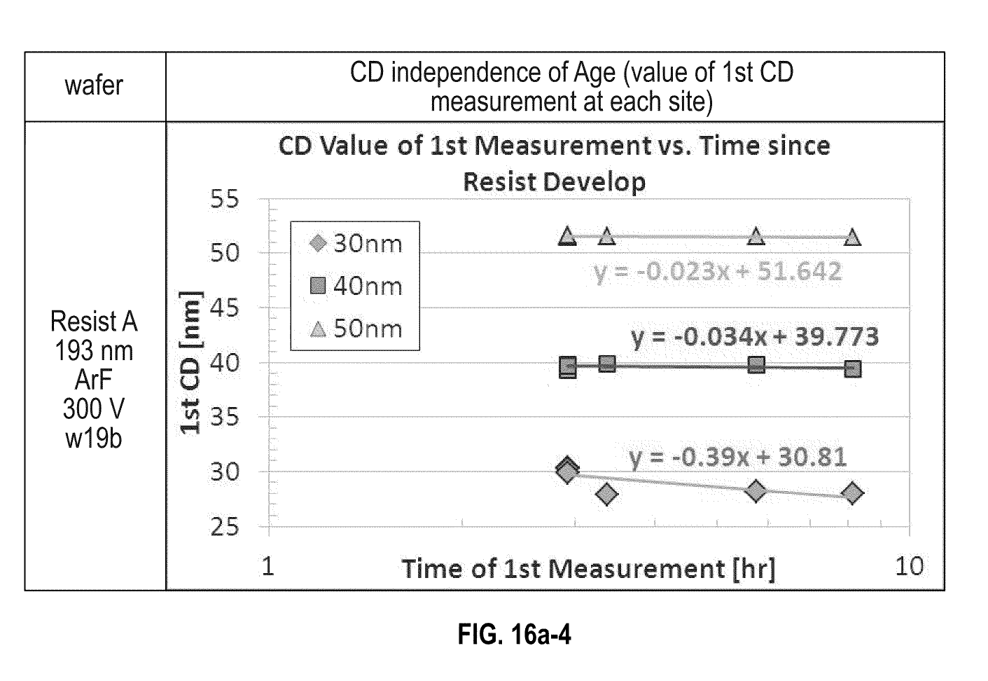

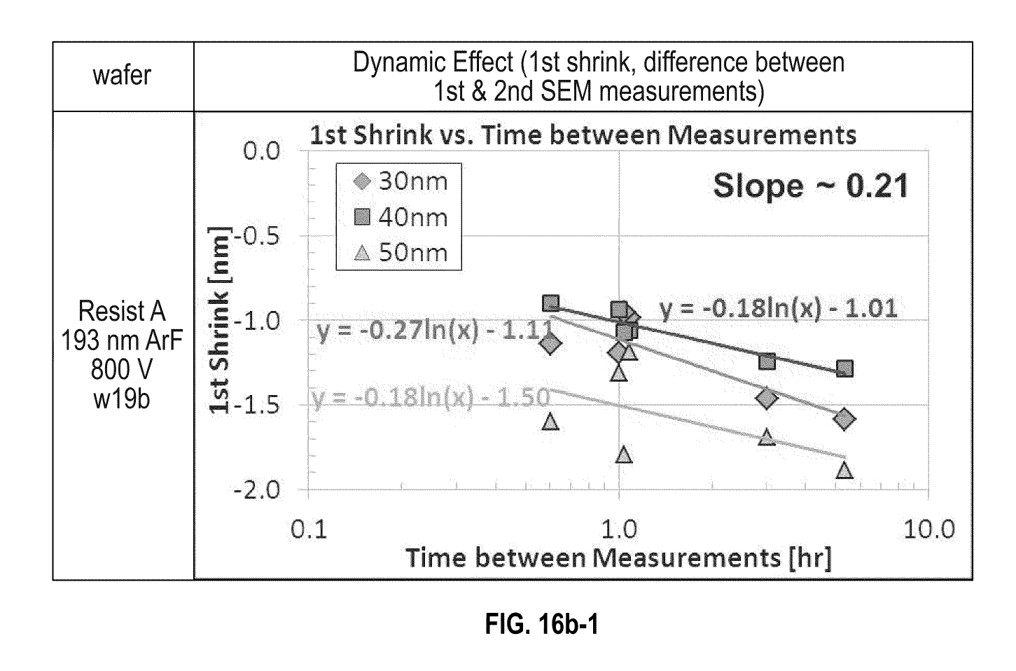

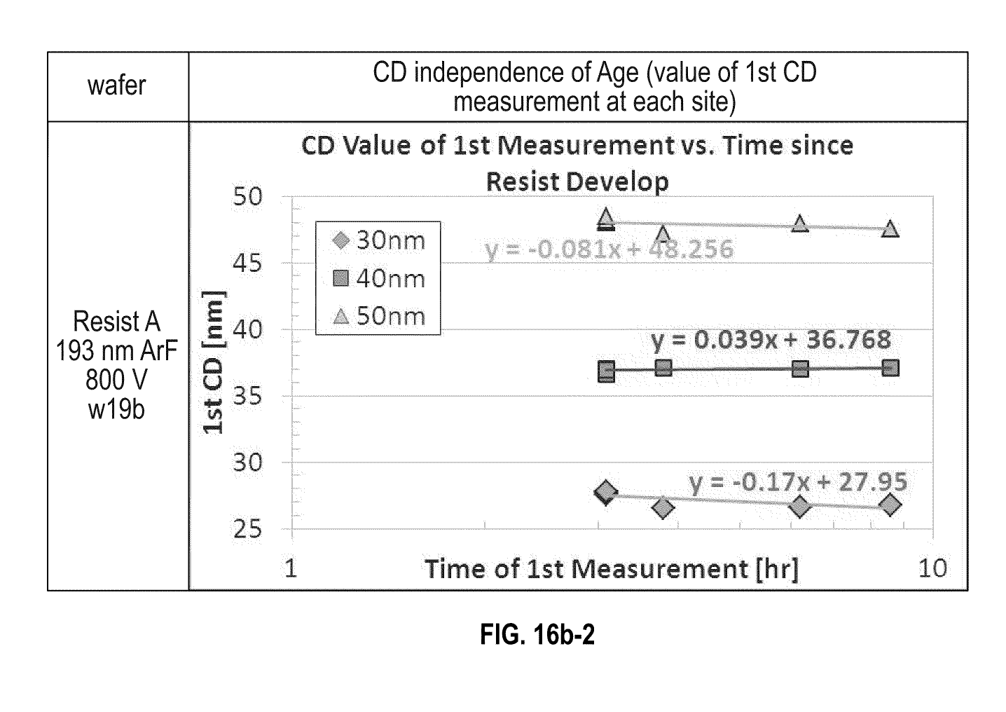

FIGS. 13-15 show the static curves for the 30 nm, 40 nm and 50 nm dense lines, along with insets of sample images of the features; FIGS. 16a-b, 17 and 18 show the dynamic shrinkage and the age independence of first CD. The different curves represent the static shrinkage at different photoresist ages. Six or seven different static experiments were performed for each wafer at different times, but here to facilitate presentation, similar curves have been average by broader time periods.

Static Shrinkage Results

For the static case, beam energy was a variable among the three data sets for the baseline 193 nm-type EUV resist in FIG. 13. Several curves are shown, each reflect the resist at a different age after processing. These curves have slightly different initial CD values, as site-to-site uniformity was not perfect, yet since the curves mostly run parallel to each other, shrinkage is much the same. The shrinkage seen occurs because charge build-up activates the photoresist. Once activated, the photoresist undergoes a chemical change that results in a volume loss. The volume loss is therefore useful in determining the amount of charge build-up because the photoresist has threshold sensitivity.

However, the curve in the baseline 193 nm-type resist at 500 V in FIG. 13 corresponds to the ˜1 month-old resist features. This curve has smaller amplitude of total shrinkage over the 10 doses, for all three of the feature sizes, and demonstrates that the resist likely reacts chemically to charging at a slower rate after it is aged. For other photoresists that have been measured, including those in [7][8], this phenomenon exhibits mixed results; it is probable, that this charging variation due to photoresist age occurs to varying degrees for different photoresists. Note that for these other materials; however, the amounts of data are not as extensive, making it difficult to discern this trend from real site-to-site variation. Results for other materials are then less conclusive.

All the observed behaviors are typical. The initial CD measurement was lower for higher V, implying that charging induced chemistry happens within the first measurement using higher SEM V. These curves of the measured CD values, apparently show larger total charging induced chemical amplitude over the ten measurements at the lower V, but this omits the shrinkage within the first measurement (0th shrink); consequently the real total shrinkage is still expected to be higher with higher V since charging induced chemistry is a function of the charge accumulation. Also, larger initial linewidth leads to larger amplitude of shrinkage within the ten doses, as observed and simulated in previous works [5]. Thus these curves behave as expected.

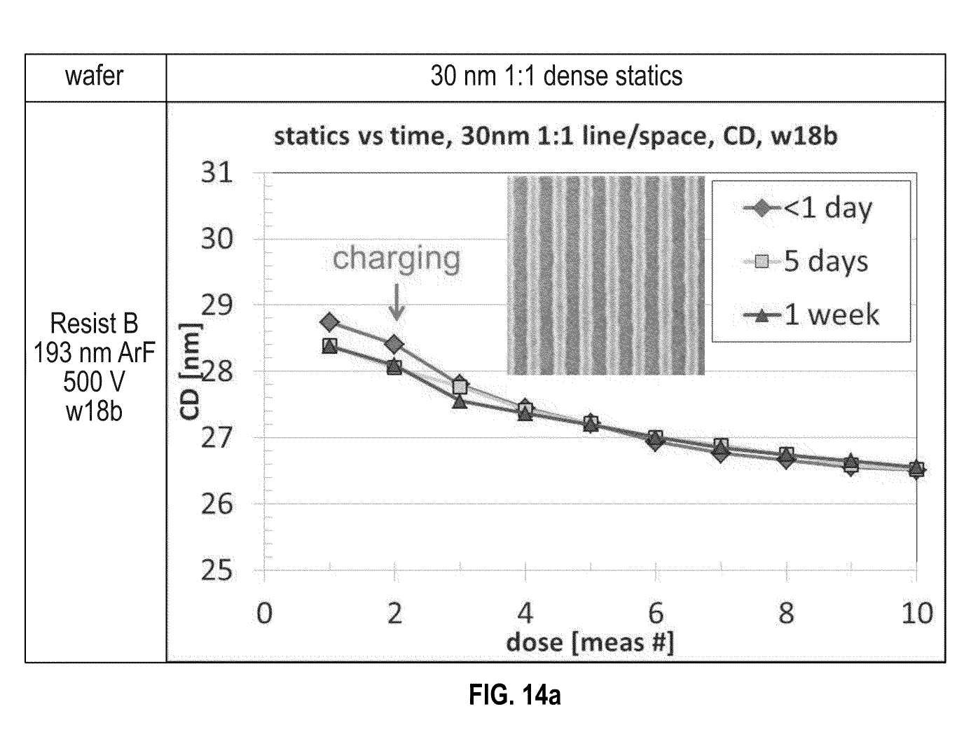

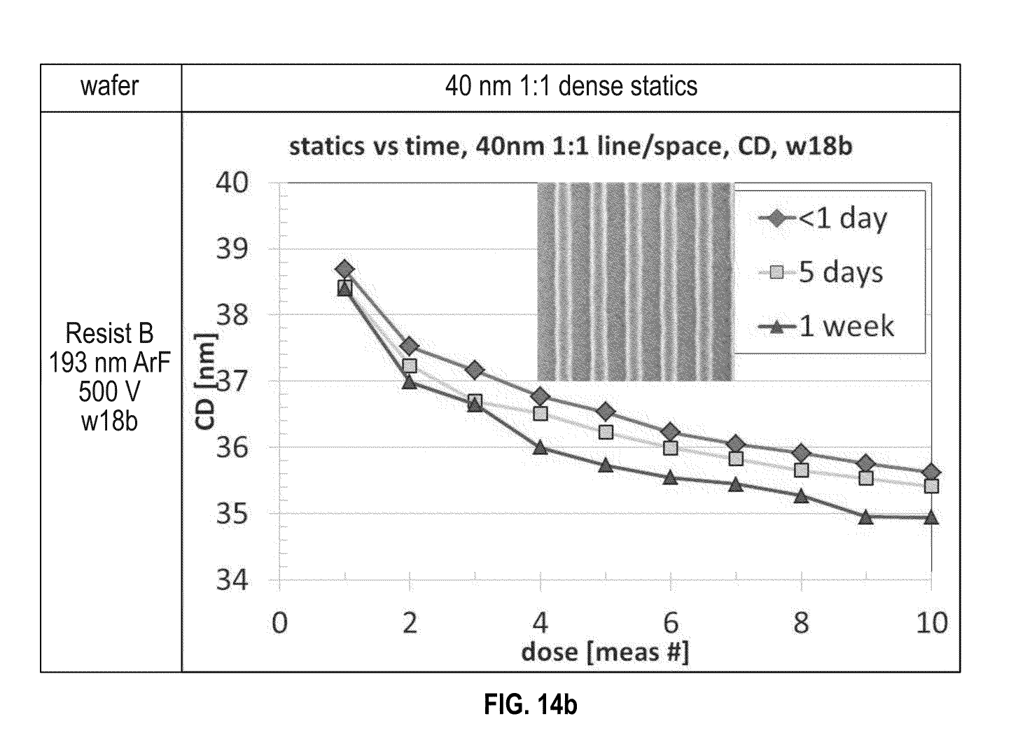

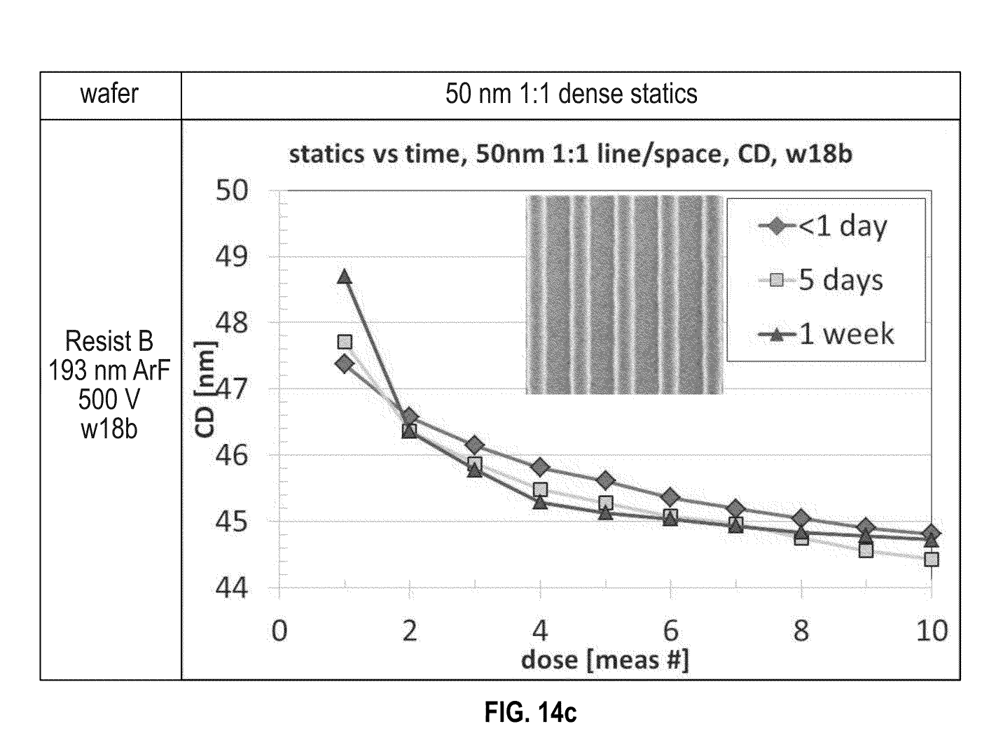

The static shrinkage results at 500 V for the second 193-type EUV resist (resist B) are shown in FIG. 14. These curves behave normally except for the second measurement of the 30 nm dense results, which shows that a charging effect is becoming apparent. Confidence in this subtle (yet important) data point is high, as these are 25 line averages, and are seen for all the static curves in that graph, all taken at different times.

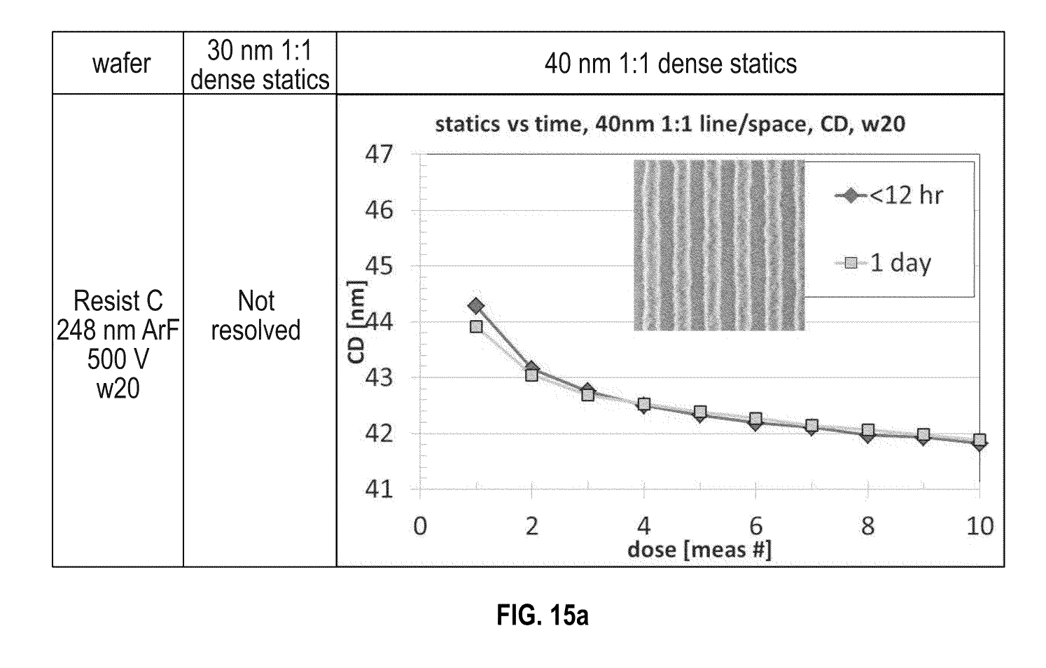

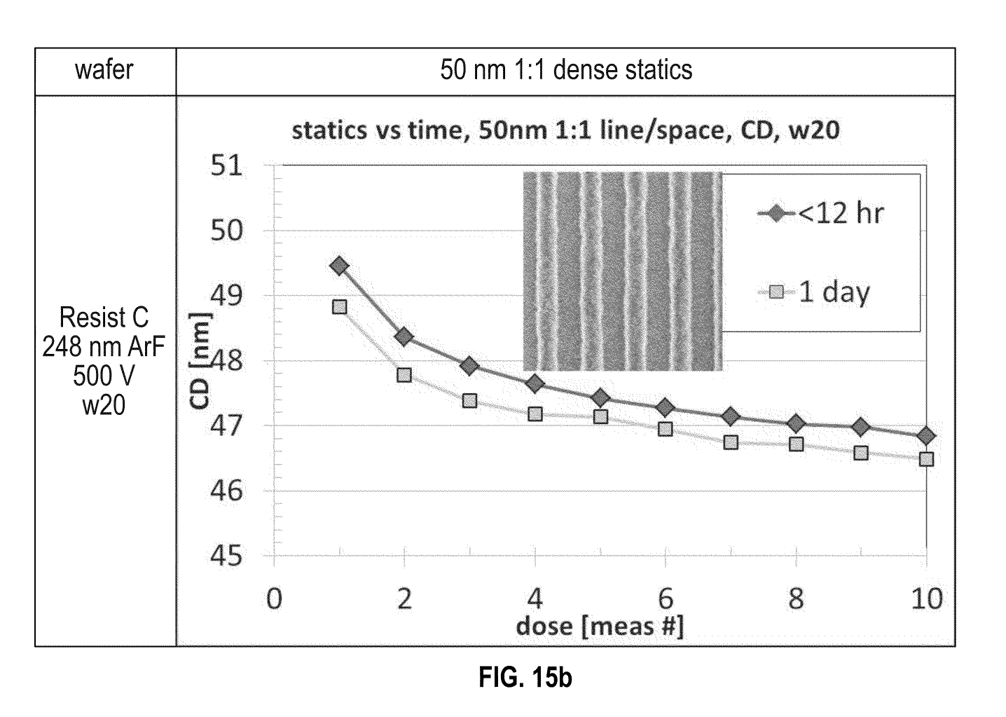

The static shrinkage results at 500 V for the 248-type EUV resist (resist C) are shown in FIG. 15. The 30 nm dense features did not resolve with this photoresist, hence the dataset includes only the 40 nm and 50 nm dense features. As shown, the resist C curves behave normally.

Dynamic Shrinkage Results

FIGS. 16a-b, 17 and 18 show the dynamic shrinkage and the age independence of first CD for resists A, B and C, respectively.

On the left in FIGS. 16a-b, 17 and 18 are the results of the dynamic shrinkage experiments for each resist; results for 30 nm, 40 nm and 50 nm 1:1 dense lines are shown. The y-axis plots the first charging induced shrinkage, which is the difference between the first and second SEM measurements of site groups a and b, with the time interval between measurements plotted logarithmically on the x-axis. Among these results, several trends are evident. The first is that the dynamic effect affects some of the photoresists, including valid logarithmically-decaying lines-of-best-fit, confirming that the results shown in FIG. 9 and reported in [7][8] was not an isolated incident. In fact, in the results below, both the 193 nm-type photoresists (A and B) exhibit this dynamic effect, while the 248 nm-type resist (C) does not. Note too that the past results in FIG. 9 were derived from a 193 nm-type photoresist, although it had undergone immersion ArF lithography. Thus, a common trait in these 193 nm-type photoresist chemistries apparently enables this phenomenon, irrespective of the exposure type used.

Another important trend among the dynamic shrinkage results is how shrinkage scales with feature size. In general, dynamic shrinkage curves run roughly parallel with slope, basically independent of initial CD, but with different y-offsets, denoting different static shrinkage between the first and second CD-SEM measurements. The value of the shrink increases in magnitude with more time between measurements (shrinkage is negative, but the size of the change gets larger with time). Also note that the magnitudes of these y-offsets of the dynamic shrinkage curves seem to be larger for larger CD features—the size of the effect roughly scales with initial CD.

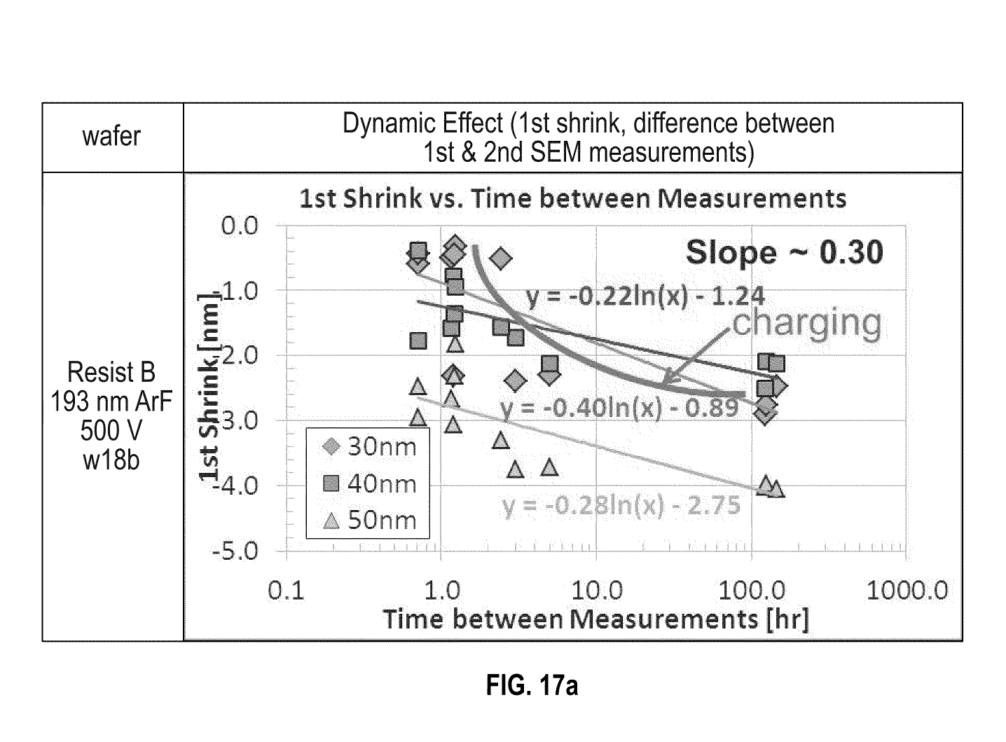

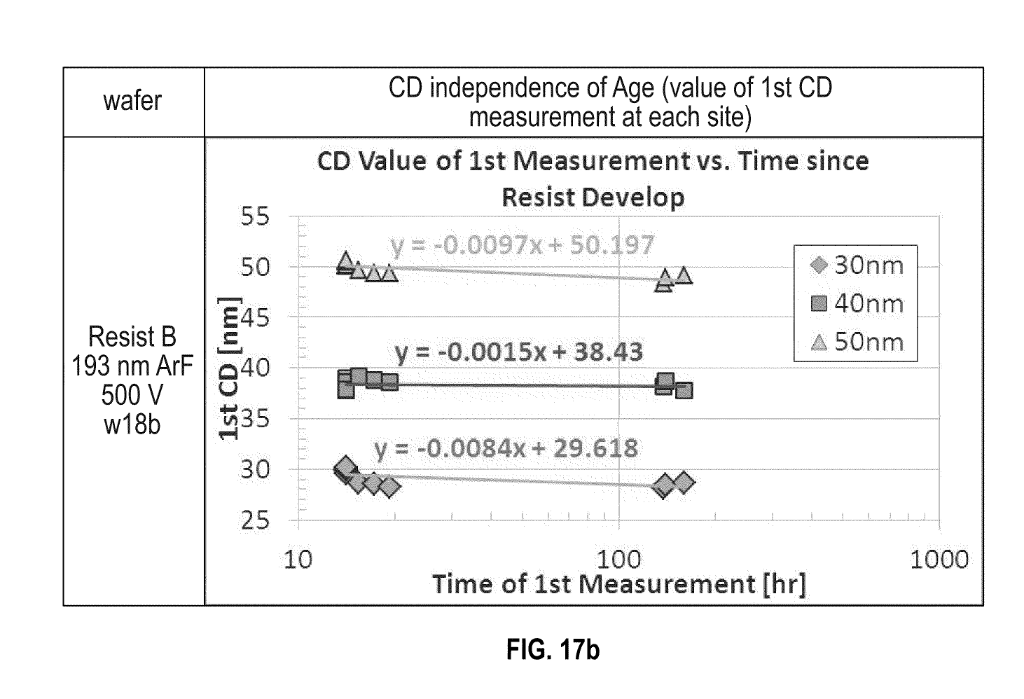

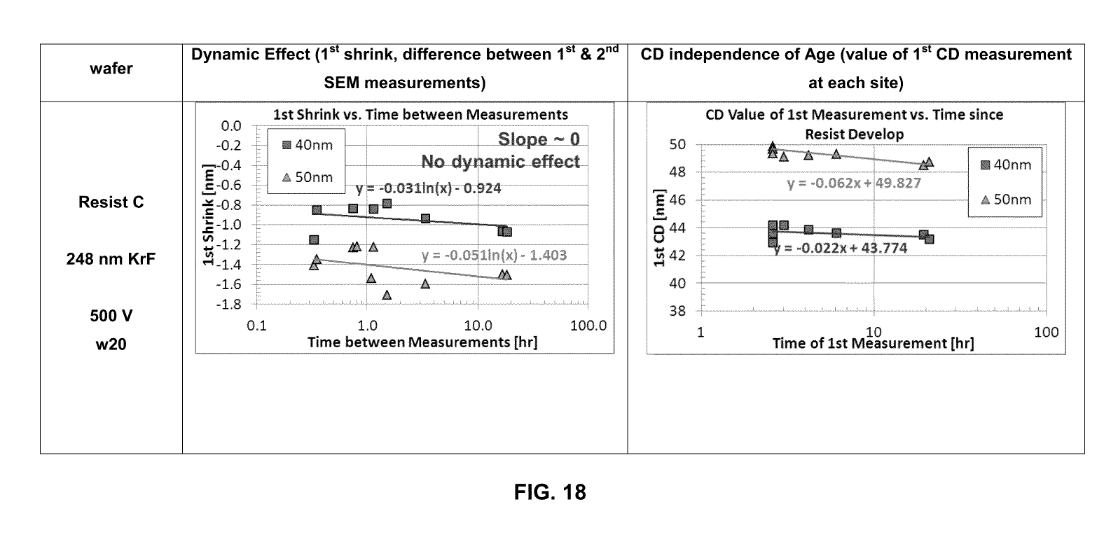

The effect of beam voltage is also explored for resist A, in FIG. 16. The y-offsets and the slopes (coefficients of the logarithmic fits) seem to be larger with lower V, such that the effect is more pronounced at the lower beam energies. Since the 0th shrink, the shrinkage occurring during the first measurement should be greater at higher V, thus less of the shrinkage progresses after the first measurement, so it must progress more slowly at higher V.

Whereas charging is shown to be significant in FIG. 14 (w18b static results), the dynamic effect curve for the 30 nm dense lines in FIG. 17 has a positive offset and shows a non-linear pattern similar to exponential decay. It should be noted that what is plotted is the differences between the first and second SEM measurements with varying times between the measurements. The charging statics resulted in the apparent CD (as seen by the CD-SEM) increasing in the short term. The decay pattern on the dynamic effect graph implies that over time, with the wafer removed from the tool and exposed to air, the positive effect on the CD from the first dose gradually decreases. We hypothesize that his would be consistent with a capacitive discharge.

On the right in FIG. 16a-b, 17 and 18, the CD of the resist as first measured by the CD-SEM is stable with time, implying that without the SEM dose, the resist features generally do not shrink as they age. While a slight downward slope (<0.01 nm per hour) is seen, it is quite insignificant in terms of photoresist in high volume manufacturing (HVM), where the next processing steps occur within minutes (or worst case, hours). This CD independence of resist age is important support for the dynamic results on the left, since it shows that any effects seen in the graphs are due to something else.

Finally, linewidth roughness (LWR) was measured along with all CD measurements. No systematic dynamic effect was observed for LWR, and the static curves were flat with dose.

6.2.6. Discussion

Charging

Resist B exhibited a minimal amount of charging early in the static shrinkage curve for the 30 nm dense features, as shown in FIG. 14. This effect is seen at only the smallest, densest feature (30 nm 1:1), where the space between lines is most confined. As the spaces become progressively less confined, for example moving from 30 nm 1:1 dense features to 40 nm 1:1 and 50 nm 1:1 features for resist B (FIG. 14), the changing shape of the shrinkage curve, a “charging hump,” becomes unobservable and thus insignificant. The semiconductor industry is moving to tighter pitched geometries and smaller feature sizes, so the charging ‘build-up’ is expected to get worst with the rapidly advancing technology node changes. Therefore an SEM sample film stack, which includes photoresist and photoresist—like underlayer (e.g. carbon, hydrogen and oxygen—thus has no charge conductivity) should be expected to continue to manifest charging characteristics. Chemically amplified photoresist, which is e-beam sensitive, will manifest the charging phenomenon as film shrinkage. The light exposure, by backscattered and secondary electrons, is in effect acting like flare (and exposure in an unintended area).

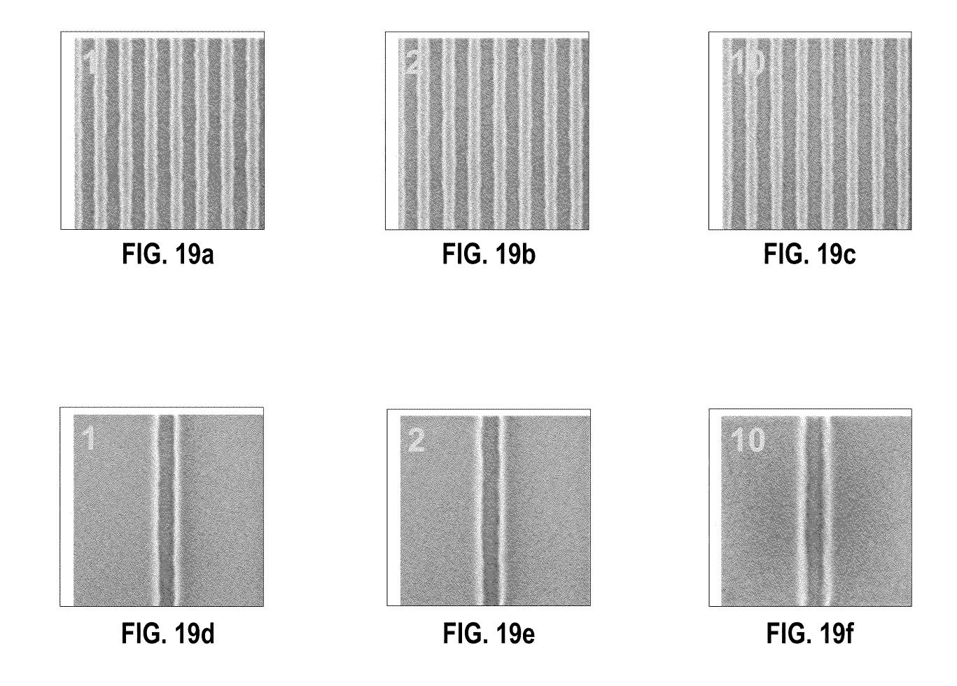

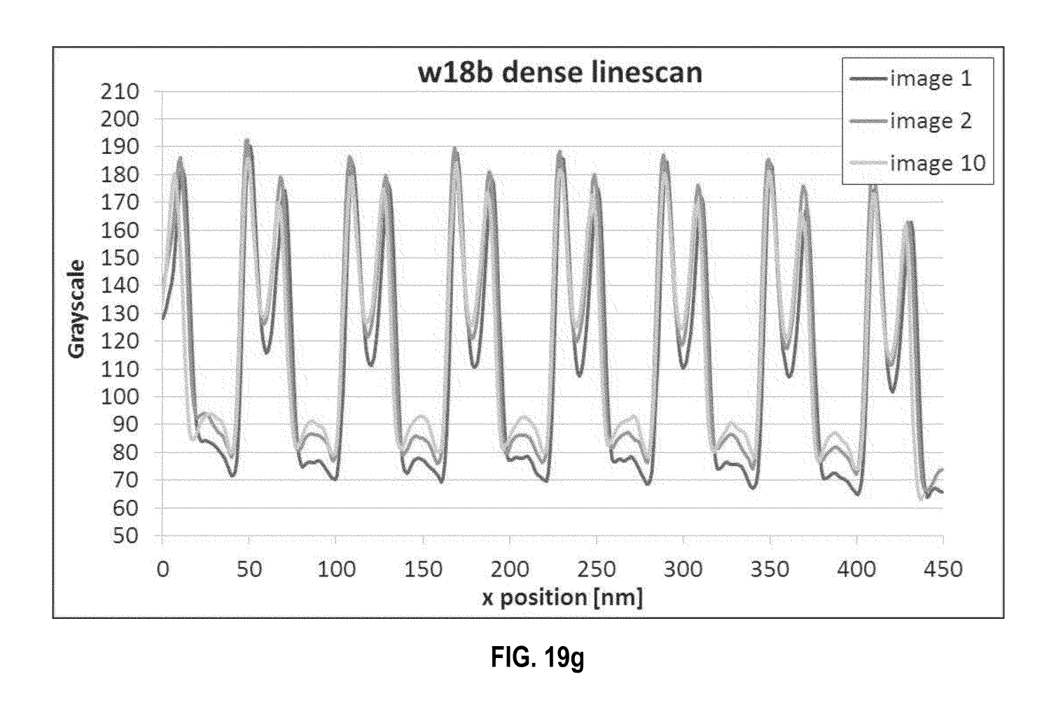

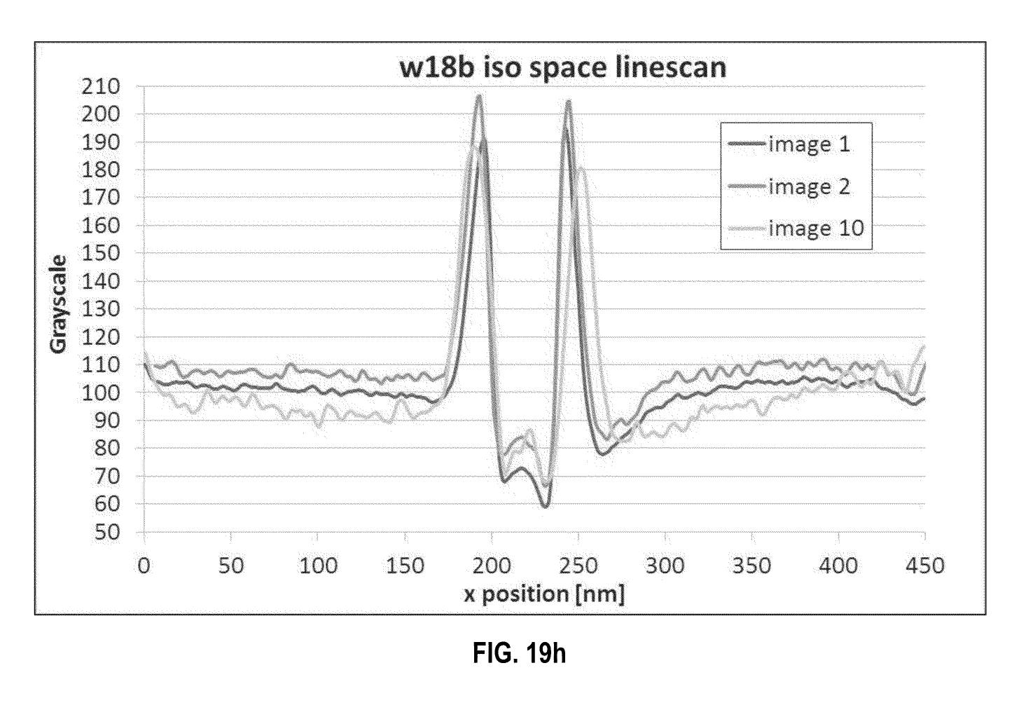

FIGS. 19a-h shows experimental evidence from the 30 nm isolated space features of wafer 18b (resist B) for which the charging signature was observed in the static shrinkage curves of FIG. 14. Intensity linescans quantitatively show increases in the background from the spaces between features (the darker regions in the images, which are the valleys in FIGS. 19g and 19h), which is easy to see in the example of the isolated space feature. The broadening of the sidewalls is also visible, although this is likely because the top CD shrinks much more than the bottom CD. The isolated space linescan (FIG. 19h) also shows that the background intensity in the bottom of the space appears to increase abruptly between the first and second image and then stabilizes so that this background intensity does not increase much further by the 10th image.

The wafer 18b dynamic shrinkage results for resist B (FIG. 17), demonstrates a decay curve for the 30 nm dense features, this is further support for charging underlying this effect. What are plotted are the differences between the first and second SEM measurements with varying times between the measurements. The charging due to the static measurements resulted in the apparent CD (as seen by the CD-SEM) not shrinking as much in the short term. The decay pattern on the dynamic effect graphs implies that after many hours, with the wafer removed from the tool and exposed to the fab's air, the positive effect on the CD of the linewidth from the first dose gradually decreases, as with a capacitive discharge. Another explanation could be that the photoresist response, which is an equilibrium reaction, showed that the chemical amplification reaction was not fully initiated at the low ‘e-beam dose’ allowing the film to recover; charge dissipation.

CD-SEM metrologists are familiar with the phenomenon that small trenches or contact holes in oxide (small, confined spaces in an electrical insulator) charge with CD-SEM dose, making the space feature appear narrow due to the charging causing local electric fields at the base of the line features. The effect results in the bending of electron trajectories and alters the intensity of the collected signal. In this experiment, we measure linewidths, not spaces, so any charging would cause these lines to show an apparent growth under the CD-SEM. As with the contact hole example mentioned above, this apparent growth is not real growth—it is an artifact of the CD-SEM measurement caused by the charging, and manifests itself as a CD measurement error. As successive static measurements are taken of such charging features, the charge builds until saturation. As a result, the CD measurement of these line features should increase and then saturate.

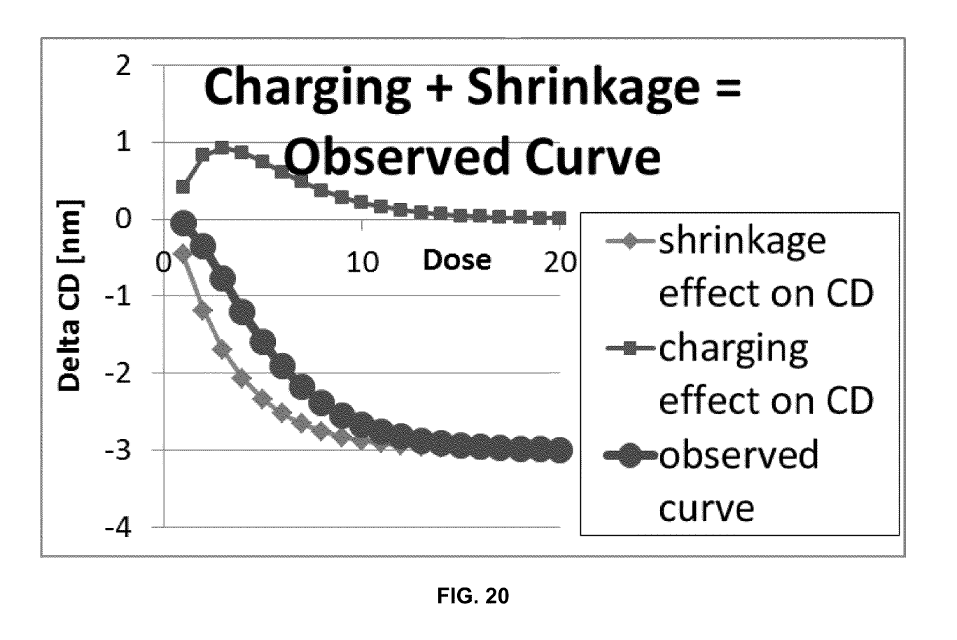

However, photoresist target lines also shrink with electron beam dose. As the lines shrink, the physical space between the lines grows and becomes less confined, such that as the charging increases and saturates, the electric field initially increases but then decreases due to the reduction of confinement from the shrinkage. Thus, we see an interesting interplay of the shrinkage and charging. Yet, the shrinkage changes the geometry to reduce the net effect of the charging on the CD measurement. See FIG. 20 for an illustration of how these two components compete, and how their sum dictates the shape of the static curves under significant charging. The e-beam exposure is present in the resist film surface and the unexposed areas. The shrinking phenomenon is therefore three dimensional, creating a photoacid rich envelope within the photoresist line. The photoresist ‘dose sensitivity’ would also be a factor in driving the level of charging behavior. Lower dose requiring photoresist would thus be more sensitive to charging. There is an example of that when considering the results of the 248 nm photoresist versus the 193 nm: the 193 nm system is more sensitive.

In our subtle test case, the shrinkage component outpaces the apparent growth from the charging component after just a few measurements and the CD measurements continue to shrink.

This observation is not surprising, since all the photoresist used in this study are chemically amplified; one exposure event can create multiple photoacid. Charging at this point is just becoming significant because the diminished source power in EUV exposure tools is pushing the industry to faster photospeed resist systems. However, this is notable because slightly smaller spaces should exhibit this charging effect more strongly, which implies eventual metrology complications and would faster photospeed photoresist systems.

Application of SEMATECH Shrinkage Model

The SEMATECH profile shrinkage model was then applied to the static shrinkage results. This model predicts CD-SEM-induced shrinkage behavior of photoresists using a finite element analysis of energy deposition. Details of the model are documented in previous works [4][5][6].

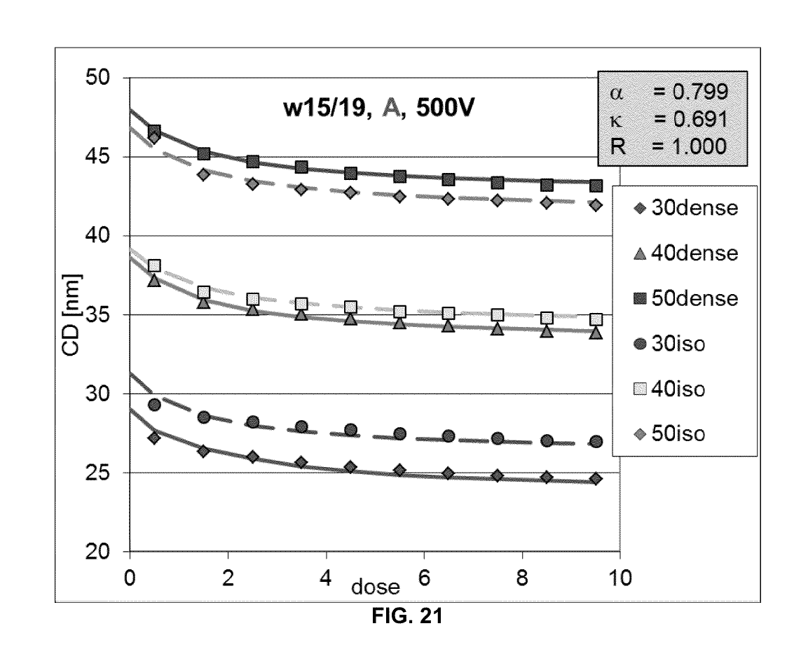

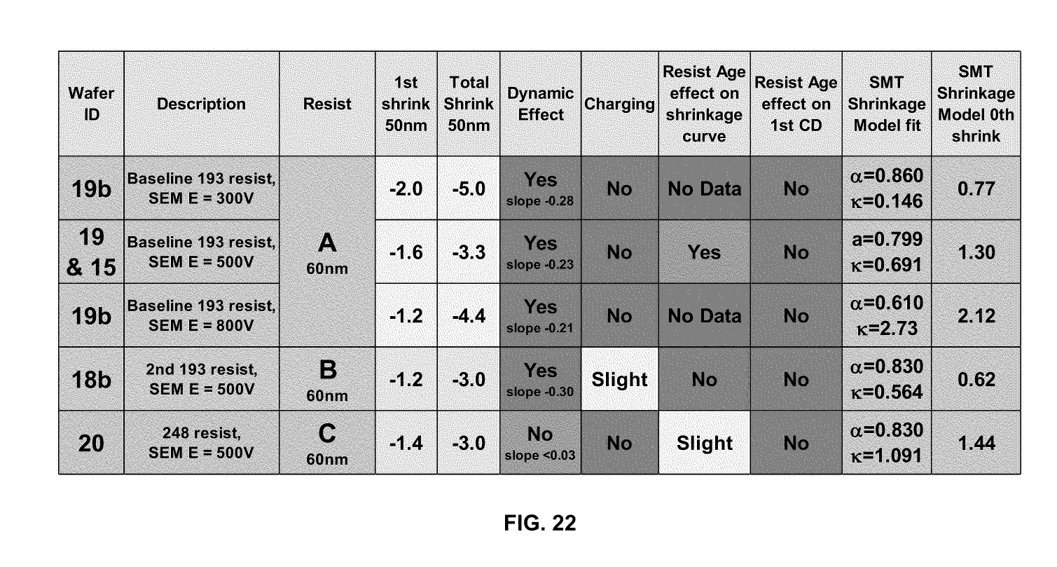

For all cases in this work (resists A, B and C, including resist A with different V values) the model was easily fit to the family of static shrinkage curves to yield values for the model parameters, shrinkage factor α and kinetic rate κ, and range factor R. In these fits, reasonable values were found for all α, κ and R=1 for all photoresist/SEM condition combinations. An example of such a fit is shown in FIG. 21. For brevity, the other fits are not shown, but the obtained parameter values are reported in FIG. 22.

6.2.7. Conclusions

In this example, a DOE was performed on various types of EUV photoresists, with variations in SEM V and feature sizes, to explore the static and dynamic shrinkage effects caused by SEM metrology of these important upcoming materials. All the results for the DOE are summarized in FIG. 22. Several significant observations and trends are readily apparent. First are the trends in static shrinkage behavior among the three EUV photoresists. As shown in previous work, shrinkage is greater within the first measurement with higher V, although some lesser total shrinkage (not including the 0th shrink) is evident within the 10 static measurements. This is supported by the fact that the first CD value is lower for higher V, as all the lines should have, on average, begun to shrink with the same value. For the static results, the SEMATECH shrinkage model could easily model the data sets that were not corrupted by charging. The 0th shrink trends are sensible through V for the baseline 193 nm-type resist (resist A); higher V precipitates a faster shrink (higher K) with larger amplitude (lower a), implying more damage to the resist is caused by the higher V imaging conditions, as is expected.

For the dynamic shrinkage effects, all of the 193 nm-type EUV photoresists exhibited a long-term decay with time after the first dose of electron beam, while the 248 nm-type resist did not. The magnitude of the dynamic effect, in terms of both offset and slope, seemed to roughly scale with initial feature size. Also, the dynamic effect seemed smaller when activated by a higher V electron beam, and smaller with lower V electron beams.

All the photoresists seemed to remain stable in terms of the first measured CD, independent of resist age, meaning that the linewidths did not shrink on their own without another factor influencing them, such as SEM measurements (electron exposure). A small downward slope was deemed insignificant. In one case, the static shrinkage curve changed amplitude when the photoresist was aged approximately one month, in contrast to features fresh off the lithocell; in other cases, the effect might also have been visible but difficult to conclusively distinguish from real sample variation. In other cases, the static shrinkage curves continued to run parallel regardless of resist age.

In general, the EUV photoresists behave much like their historic immersion 193 nm and dry 193 nm predecessors. The static shrinkage followed the established using the SEMATECH model. The dynamic effect was seen with all 193 nm-type resists, consistent with the previous findings, but not seen with the 248 nm-type resist.

Finally, as features and pitches continue to shrink, charging will become a more significant factor in CD-SEM measurements of such features. The photoresists formulations exhibit varying degrees of charging behavior (compare resist B with the others). Since the entire industry is adopting EUV lithography to shrink pitch and CD, these effects will likely become more problematic in the future. These results provide important clues to understanding the causes of the static and dynamic shrinkage mechanisms.

### REFERENCES

[1] Bunday, B., Azordegan, A., Vladar, A., Singh, B., Banke, B., Hartig, C., Archie, C., Joy, D., Solecky, E., Cao, G., Villarrubia, J., and Postek, M. Unified Advanced Critical Dimension Scanning Electron Microscope (CD-SEM) Specification for sub-65 nm Technology (2010 Version). ISMI Tech Transfer document ID#04114595G-ENG, December 2010. Non-confidential, available on SEMATECH website at www.sematech.org.
[2] Bunday, B., Cordes, A., Orji, N. G., Piscani, E., Cochran, D., Byers, J., Allgair, J., Rice, B., J., Byers, J., Avitan, Y., Peltinov, R., Bar-Zvi, M., & Adan, O. “Characterization of CD-SEM Metrology for iArF Photoresist Materials,” Proc SPIE, v6922, chapter 1A, 2008.
[3] Bunday, B., Allgair, J., Rice, B. J., Byers, J., Avitan, Y., Peltinov, R., Bar-Zvi, M., Adan, O., Swyers, J., & Shneck, R. “SEM Metrology for Advanced Lithographies,” Proc SPIE 2007, v6518, chapter 2B.
[4] Bunday, B., Cordes, A., Allgair, J., Tileli, V., Avitan, Y., Peltinov, R., Bar-Zvi, M., Adan, O., Cottrell, E., & Hand, S. “Phenomenology of electron-beam induced photoresist shrinkage trends,” Proceedings of SPIE Metrology, Inspection, and Process Control for Microlithography 2009, v7272, pp 72721B-72721B-15, 2009.
[5] Bunday, B., Cordes, A., Allgair, J., Aguilar, D., Tileli, V., Thiel, B., Avitan, Y., Peltinov, R., Bar-Zvi, M., Adan, O., & Chirko, K. “Electron-beam induced photoresist shrinkage influence on 2D profiles.” Metrology, Inspection, and Process Control for Microlithography XXIV. J. Proceedings of the SPIE, Volume 7638, pp. 76381L-76381L-21 (2010).
[6] Benjamin Bunday, Aaron Cordes, Andy Self, Lorena Ferry, and Alex Danilevsky. “Experimental validation of 2-D profile photoresist shrinkage model.” Metrology, Inspection, and Process Control for Microlithography XXV. J. Proceedings of the SPIE, Volume 7971, 79710W (2011).
[7] Benjamin Bunday, Aaron Cordes, Carsten Hartig, John Allgair, Alok Vaid, Eric Solecky, and Narender Rana. “Tool-to-tool matching issues due to photoresist shrinkage effects.” Metrology, Inspection, and Process Control for Microlithography XXV. Proc SPIE v7971, 79710B (2011).
[8] Benjamin Bunday, Aaron Cordes, Carsten Hartig, John Allgair, Alok Vaid, Eric Solecky, and Narender Rana. “Time-dependent electron-beam induced photoresist shrinkage effects.” JM3, pending.
[9] J. Thackeray, J. Cameron, M. Wagner, S. Coley, O. Ongayi, W. Montgomery, D. Lovell, J. Biafore, A. Ko, “Optimization of Low Diffusion EUV Resist for Linewidth Roughness and Pattern Collapse on Various Substrates”, Proc. SPIE Paper #8325-8 in press (2012).
[10] International Organization for Standardization 1993, International Vocabulary of Basic and General Terms in Metrology-ISO, 60P, Geneva, Switzerland, ISBN 92-67-01075-1, 1993.
[11] SEMI E89-0999, Guide for Measurement System Capability Analysis, 1999.
[12] J. Wu, W. Huang, K. Chen, C. Archie, M. Lagus. “Investigation on the mechanism of the 193-nm resist linewidth reduction during the SEM measurement”. Proc. SPIE, Vol. 4345, pp. 190-199, 2001.
[13] The International Technology Roadmap for Semiconductors (San Jose: Semiconductor Industry Association, 2010); available from the Internet: http://member.itrs.net.
[14] Bunday, B., Rijpers, B., Banke, W., Archie, C., Peterson, I., Ukraintsev, V., Hingst, T., and Asano, M. “Impact of Sampling on Uncertainty: Semiconductor Dimensional Metrology Applications,” Proc. SPIE 6922, 6922-0X, pp 0X-1 to 0X-22, March, 2008.

A sample of methods, materials and devices that are described herein are as follows:

A method for producing a surface of interest in the manufacture of an integrated device, the method comprising the steps of:

(a) providing a substrate;

(b) positioning a silicon-comprising under layer on the substrate; and

(c) positioning a patterned photoresist image layer on the under layer.

The method for producing a surface of interest wherein the surface is lithographically or non-lithographically fabricated.

The method for producing a surface of interest wherein the silicon-comprising under layer comprises a nondoped or doped conjugated or conducting polymer comprising silicon.

The method for producing a surface of interest wherein the silicon-comprising under layer comprises a silicon-containing antireflection coating (SiARC).

The method for producing a surface of interest wherein step (b), the step of positioning a silicon-comprising under layer on the substrate, comprises the steps of depositing an organic layer and depositing silicon on the organic layer.

The method for producing a surface of interest wherein the step of depositing silicon on the organic layer comprises the step of vapor-depositing silicon on the organic layer or the step of silylating the organic layer.

The method for producing a surface of interest wherein the substrate comprises silicon.

The method for producing a surface of interest wherein the silicon-comprising substrate is a silicon wafer.

The method for producing a surface of interest wherein step (c), the step of positioning the patterned photoresist image layer on the silicon-comprising under layer comprises spin coating the photoresist image layer on the under layer.

The method for producing a surface of interest wherein the patterned photoresist image layer comprises at least one structure defining an opening in the patterned photoresist image layer.

The method for producing a surface of interest wherein the structure defining the opening is dimensionally equivalent to a desired opening in the integrated device.

The method for producing a surface of interest wherein the lithographically fabricated surface comprises a feature having at least one critical dimension (CD).

A method for inspecting or measuring a feature on a lithographically fabricated surface of interest in the manufacture of an integrated device, the method comprising the steps of:

(a) providing a substrate;

(b) positioning a silicon-comprising under layer on the substrate;

(c) positioning a patterned photoresist image layer on the under layer; and

(d) delivering an electron beam to the surface of interest.

The method for inspecting or measuring a feature on a lithographically fabricated surface of interest wherein the surface is lithographically or non-lithographically fabricated.

The method for inspecting or measuring a feature on a lithographically fabricated surface of interest wherein the silicon-comprising under layer comprises a nondoped or doped conjugated or conducting polymer comprising silicon.

The method for inspecting or measuring a feature on a lithographically fabricated surface of interest wherein the silicon-comprising under layer comprises a silicon-containing antireflection coating (SiARC).

The method for inspecting or measuring a feature on a lithographically fabricated surface of interest wherein step (b), the step of positioning a silicon-comprising under layer on the substrate, comprises the steps of depositing an organic layer and depositing silicon on the organic layer.

The method for inspecting or measuring a feature on a lithographically fabricated surface of interest wherein the step of depositing silicon on the organic layer comprises the step of vapor-depositing silicon on the organic layer or the step of silylating the organic layer.

The method for inspecting or measuring a feature on a lithographically fabricated surface of interest wherein the substrate comprises silicon.

The method for inspecting or measuring a feature on a lithographically fabricated surface of interest wherein the silicon-comprising substrate is a silicon wafer.

The method for inspecting or measuring a feature on a lithographically fabricated surface of interest wherein step (c), the step of positioning the patterned photoresist image layer on the silicon-comprising under layer comprises spin coating the photoresist image layer on the under layer.

The method for inspecting or measuring a feature on a lithographically fabricated surface of interest wherein the patterned photoresist image layer comprises at least one structure defining an opening in the patterned photoresist image layer.

The method for inspecting or measuring a feature on a lithographically fabricated surface of interest wherein the structure defining the opening is dimensionally equivalent to a desired opening in the integrated device.

The method for inspecting or measuring a feature on a lithographically fabricated surface of interest wherein the lithographically fabricated surface comprises a feature having at least one critical dimension (CD).

An under layer comprising silicon.

The under layer comprising a nondoped or doped conjugated or conducting polymer comprising silicon.

The under layer comprising a silicon-containing antireflection coating (SiARC).

The underlayer comprising: a nondoped or doped conjugated or conducting polymer comprising silicon, and/or a silicon-containing antireflection coating (SiARC).

The present invention is not to be limited in scope by the specific embodiments described herein. Indeed, various modifications of the invention in addition to those described herein will become apparent to those skilled in the art from the foregoing description. Such modifications are intended to fall within the scope of the appended claims.

All references cited herein are incorporated herein by reference in their entirety and for all purposes to the same extent as if each individual publication, patent or patent application was specifically and individually indicated to be incorporated by reference in its entirety for all purposes.

The citation of any publication is for its disclosure prior to the filing date and should not be construed as an admission that the present invention is not entitled to antedate such publication by virtue of prior invention.

What is claimed is:

1. A method for producing a surface of interest in the manufacture of an integrated device, the method comprising the steps of:
(a) providing a substrate;
(b) positioning a silicon-comprising under layer on the substrate; and
(c) positioning a patterned photoresist image layer on the under layer.

2. The method of claim 1 wherein the surface is lithographically fabricated.

3. The method of claim 1 wherein the silicon-comprising under layer comprises a nondoped or doped conjugated or conducting polymer comprising silicon.

4. The method of claim 1 wherein the silicon-comprising under layer comprises a silicon-containing antireflection coating (SiARC).

5. The method of claim 1 wherein step (b), the step of positioning a silicon-comprising under layer on the substrate, comprises the steps of depositing an organic layer and depositing silicon on the organic layer.

6. The method of claim 5 wherein the step of depositing silicon on the organic layer comprises the step of vapor-depositing silicon on the organic layer or the step of silylating the organic layer.

7. The method of claim 1 wherein the substrate comprises silicon.

8. The method of claim 7 wherein the substrate comprising silicon is a silicon wafer.

9. The method of claim 1 wherein step (c), the step of positioning the patterned photoresist image layer on the silicon-comprising under layer, comprises spin coating the photoresist image layer on the under layer.

10. The method of claim 1 wherein the patterned photoresist image layer comprises at least one structure defining an opening in the patterned photoresist image layer.

11. The method of claim 1, wherein the structure defining the opening is dimensionally equivalent to a desired opening in the integrated device.

12. The method of claim 2 wherein the surface that is lithographically fabricated comprises a feature having at least one critical dimension (CD).

13. A method for inspecting or measuring a feature on a lithographically fabricated surface of interest in the manufacture of an integrated device, the method comprising the steps of:
(a) providing a substrate;
(b) positioning a silicon-comprising under layer on the substrate;
(c) positioning a patterned photoresist image layer on the under layer; and
(d) delivering an electron beam to the surface of interest.

14. The method of claim 13 wherein the silicon-comprising under layer comprises a nondoped or doped conjugated or conducting polymer comprising silicon.

15. The method of claim 13 wherein the silicon-comprising under layer comprises a silicon-containing antireflection coating (SiARC).

16. The method of claim 13 wherein step (b), the step of positioning a silicon-comprising under layer on the substrate, comprises the steps of depositing an organic layer and depositing silicon on the organic layer.

17. The method of claim 16 wherein the step of depositing silicon on the organic layer comprises the step of vapor-depositing silicon on the organic layer or the step of silylating the organic layer.

18. The method of claim 1 wherein the substrate comprises silicon.

19. The method of claim 17 wherein the substrate comprising silicon is a silicon wafer.

20. The method of claim 13 wherein step (c), the step of positioning the patterned photoresist image layer on the silicon-comprising under layer comprises spin coating the photoresist image layer on the under layer.

21. The method of claim 13 wherein the patterned photoresist image layer comprises at least one structure defining an opening in the patterned photoresist image layer.

22. The method of claim 13, wherein the structure defining the opening is dimensionally equivalent to a desired opening in the integrated device.

23. The method of claim 13 wherein the lithographically fabricated surface comprises a feature having at least one critical dimension (CD).

24. An under layer comprising silicon, wherein the under layer comprises:
a nondoped or doped conjugated or conducting polymer comprising silicon, and/or
a silicon-containing antireflection coating (SiARC).
